(19) United States
(12) Patent Application Publication
(10) Pub. No.: US 2015/0364681 A1
(43) Pub. Date: Dec. 17, 2015

(54) NONVOLATILE STORAGE DEVICE AND METHOD OF PRODUCING THE DEVICE

(71) Applicant: Panasonic Intellectual Property Management Co., Ltd., Osaka (JP)

(72) Inventors: HIDEAKI MURASE, Osaka (JP); YOSHIO KAWASHIMA, Osaka (JP)

(21) Appl. No.: 14/726,637

(22) Filed: Jun. 1, 2015

(30) Foreign Application Priority Data
Jun. 12, 2014 (JP) 2014-121663

(51) Int. Cl. H01L 45/00

(52) U.S. Cl. CPC H01L 45/1233; H01L 45/1253; H01L 45/16

(57) ABSTRACT

A nonvolatile storage device includes a first conductive layer disposed on a substrate, a contact plug including a conductive material and disposed on the first conductive layer, a variable resistance element covering the upper surface of the contact plug, resistance of the variable resistance element changing in accordance with an voltage applied to the variable resistance element, one single insulating layer that is directly or indirectly in contact with a sidewall of the contact plug and that is directly or indirectly in contact with a sidewall of the variable resistance element, and a second conductive layer disposed on the variable resistance element.

### BACKGROUND

1. Technical Field

The present disclosure relates to a nonvolatile storage device and a method of producing the device.

2. Description of the Related Art

In recent years, miniaturization and acceleration of semiconductor devices used in electronic apparatuses have been rapidly progressed with an improvement in the performance of the electronic apparatuses. In particular, the use of large-capacity nonvolatile memories, such as flash memories, has been rapidly expanded. Furthermore, a resistive random access memory (ReRAM) using a variable resistance element has been being researched and developed as a next-generation nonvolatile memory to replace for the flash memories.

The resistive random access memory is desired that the resistance values at a low-resistance state and at a high-resistance state can be clearly distinguished from each other and that the transition between the low-resistance state and the high-resistance state is performed fast and stably.

Throughout the specification, the term “variable resistance element” refers to an element having properties of reversibly changing the resistance state (resistance value) by electrical signals and of maintaining the state. Information can be stored in a nonvolatile manner by allocating the information to the respective resistance states of a variable resistance element. Specifically, the variable resistance element has, for example, a low-resistance state having a low resistance value and a high-resistance state having a resistance value higher than that at the low-resistance state. The variable resistance element can store two values by allocating “0” to one of the two different states and allocating “1” to the other.

As an example of the variable resistance element, International Publication No. WO2008/149484 proposes a nonvolatile storage element having a variable resistance layer formed by laminating transition metal oxides having different oxygen contents between a first electrode and a second electrode. The variable resistance element changes the resistance state from the high-resistance state to the low-resistance state or from the low-resistance state to the high-resistance state by application of an electrical pulse (e.g., voltage pulse) between the first electrode and the second electrode of the variable resistance element.

### SUMMARY

One non-limiting and exemplary embodiment provides a nonvolatile storage device including a variable resistance element provided with a variable resistance layer and having a reduced risk of increasing the capacity between wirings.

In one general aspect, the techniques disclosed here feature a method for manufacturing a nonvolatile storage device, including: forming a first conductive layer on a substrate; forming a sacrificial layer covering the first conductive layer; forming a contact plug passing through the sacrificial layer to be the contact plug in contact with the first conductive layer, the contact plug including a conductive material; forming a variable resistance element covering the upper surface of the contact plug; removing the sacrificial layer other than a part of the sacrtificial layer that covers a sidewall of the contact plug; forming one single insulating layer that is directly or indirectly in contact with a side of the contact plug and that is directly or indirectly in contact with the variable resistance element; and forming a second conductive layer on the variable resistance element.

According to an embodiment of the present disclosure, in a nonvolatile storage device including a variable resistance element provided with a variable resistance layer, a risk of increasing the capacity between wirings is reduced.

It should be noted that general or specific embodiments may be implemented as a system, a method, an integrated circuit, a computer program, a storage medium, or any selective combination thereof.

Additional benefits and advantages of the disclosed embodiments will become apparent from the specification and drawings. The benefits and/or advantages may be individually obtained by the various embodiments and features of the specification and drawings, which need not all be provided in order to obtain one or more of such benefits and/or advantages.

### BRIEF DESCRIPTION OF THE DRAWINGS

FIG. 1 is a cross-sectional view schematically illustrating an example of the configuration of a nonvolatile storage device according to a first embodiment;

FIG. 2 is a cross-sectional view schematically illustrating an example of the configuration of a nonvolatile storage device according to a modification example of the first embodiment;

FIG. 3A is a cross-sectional view schematically illustrating the configuration of a nonvolatile storage device according to a first example;

FIG. 3B is a plan view schematically illustrating the configuration of a nonvolatile storage unit of the nonvolatile storage devices according to the first example;

FIG. 4A is a cross-sectional view illustrating a step in the method of producing the nonvolatile storage unit according to the first example;

FIG. 4B is a cross-sectional view illustrating a step in the method of producing the nonvolatile storage unit according to the first example;

FIG. 4C is a cross-sectional view illustrating a step in the method of producing the nonvolatile storage unit according to the first example;

FIG. 4D is a cross-sectional view illustrating a step in the method of producing the nonvolatile storage unit according to the first example;

FIG. 4E is a cross-sectional view illustrating a step in the method of producing the nonvolatile storage unit according to the first example;

FIG. 4F is a cross-sectional view illustrating a step in the method of producing the nonvolatile storage unit according to the first example;

FIG. 4G is a cross-sectional view illustrating a step in the method of producing the nonvolatile storage unit according to the first example;

FIG. 4H is a cross-sectional view illustrating a step in the method of producing the nonvolatile storage unit according to the first example;

FIG. 5 is a cross-sectional view schematically illustrating an example of the configuration of a nonvolatile storage device according to a second embodiment;

FIG. 6 is a cross-sectional view schematically illustrating the configuration of a nonvolatile storage device according to a second example;

FIG. 7A is a cross-sectional view illustrating a step in the method of producing a nonvolatile storage unit of the nonvolatile storage devices according to the second example;

FIG. 7B is a cross-sectional view illustrating a step in the method of producing the nonvolatile storage unit according to the second example;

FIG. 7C is a cross-sectional view illustrating a step in the method of producing the nonvolatile storage unit according to the second example;

FIG. 7D is a cross-sectional view illustrating a step in the method of producing the nonvolatile storage unit according to the second example;

FIG. 7E is a cross-sectional view illustrating a step in the method of producing the nonvolatile storage unit according to the second example;

FIG. 8 is a cross-sectional view schematically illustrating an example of the configuration of a nonvolatile storage device according to a third embodiment;

FIG. 9 is a cross-sectional view illustrating an example of the configuration of a nonvolatile storage device according to a third example;

FIG. 10A is a cross-sectional view illustrating a step in the method of producing a nonvolatile storage unit of the nonvolatile storage devices according to the third example;

FIG. 10B is a cross-sectional view illustrating a step in the method of producing the nonvolatile storage unit according to the third example;

FIG. 10C is a cross-sectional view illustrating a step in the method of producing the nonvolatile storage unit according to the third example;

FIG. 10D is a cross-sectional view illustrating a step in the method of producing the nonvolatile storage unit according to the third example;

FIG. 10E is a cross-sectional view illustrating a step in the method of producing the nonvolatile storage unit according to the third example;

FIG. 10F is a cross-sectional view illustrating a step in the method of producing the nonvolatile storage unit according to the third example;

FIG. 11 is a cross-sectional view schematically illustrating an example of the configuration of a nonvolatile storage device according to a fourth embodiment;

FIG. 12 is a cross-sectional view illustrating an example of the configuration of a nonvolatile storage device according to a fourth example;

FIG. 13A is a cross-sectional view illustrating a step in the method of producing a nonvolatile storage unit of the nonvolatile storage devices according to the fourth example;

FIG. 13B is a cross-sectional view illustrating a step in the method of producing the nonvolatile storage unit according to the fourth example;

FIG. 13C is a cross-sectional view illustrating a step in the method of producing the nonvolatile storage unit according to the fourth example;

FIG. 14 is a cross-sectional view schematically illustrating an example of the configuration of a nonvolatile storage device according to a fifth embodiment;

FIG. 15 is a cross-sectional view illustrating an example of the configuration of a nonvolatile storage device according to a fifth example;

FIG. 16A is a cross-sectional view illustrating a step in the method of producing a nonvolatile storage unit of the nonvolatile storage devices according to the fifth example;

FIG. 16B is a cross-sectional view illustrating a step in the method of producing the nonvolatile storage unit according to the fifth example;

FIG. 16C is a cross-sectional view illustrating a step in the method of producing the nonvolatile storage unit according to the fifth example;

FIG. 16D is a cross-sectional view illustrating a step in the method of producing the nonvolatile storage unit according to the fifth example;

FIG. 16E is a cross-sectional view illustrating a step in the method of producing the nonvolatile storage unit according to the fifth example;

FIG. 17 is a cross-sectional view schematically illustrating an example of the configuration of a nonvolatile storage device according to a sixth embodiment;

FIG. 18 is a cross-sectional view illustrating an example of the configuration of a nonvolatile storage device according to a sixth example;

FIG. 19A is a cross-sectional view illustrating a step in the method of producing a nonvolatile storage unit of the nonvolatile storage devices according to the sixth example; and

FIG. 19B is a cross-sectional view illustrating a step in the method of producing the nonvolatile storage unit according to the sixth example.

### DETAILED DESCRIPTION

### (Underlying Knowledge Forming Basis of the Present Disclosure)

The present inventors have diligently studied for reducing a risk of increasing the capacity between wirings in a nonvolatile storage device including a variable resistance element and, as a result, have obtained the following findings.

A nonvolatile storage device including a variable resistance element can be produced by, for example, as follows: A first interlayer insulating layer is formed on a first conductive layer (lower wiring) disposed on a substrate. A first contact is formed so as to pass through the first interlayer insulating layer and be physically connected to the first conductive layer. Materials for a lower electrode, a variable resistance layer, and an upper electrode are deposited in this order so as to cover the first contact exposing on the surface of the first interlayer insulating layer. A mask is disposed on the material for the upper electrode, and etching is performed to form a variable resistance element including a lower electrode, a variable resistance layer, and an upper electrode. Subsequently, a second interlayer insulating layer is formed so as to cover the variable resistance element. A second contact is formed so as to pass through the second interlayer insulating layer and be connected to the upper electrode. A second conductive layer (upper wiring) is formed so as to cover the second contact exposing on the surface of the second interlayer insulating layer.

The inventors have revealed that a variable resistance element formed by the method described above has a risk of damaging the surface of the first interlayer insulating layer and forming a layer having a high dielectric constant (hereinafter, referred to as damaged layer) between the first interlayer insulating layer and the second interlayer insulating layer. The damaged layer is formed by, for example, the following mechanism.

First, in formation of a variable resistance element by etching, the surface of the exposing first interlayer insulating layer is exposed to the etching gas and is thereby damaged.

Secondly, in formation of a sidewall protective layer (insulating layer) on the sidewall of the variable resistance layer of the variable resistance element, when the insulating layer deposited on the variable resistance element and the first interlayer insulating layer is removed by etching, the surface of the exposing first interlayer insulating layer is exposed to the etching gas and is thereby damaged.

Thirdly, in oxygen plasma treatment for removing the etching gas, the exposed first interlayer insulating layer is exposed to the oxygen plasma and is thereby damaged.

Fourthly, in oxygen plasma treatment for oxidizing the sidewall of the variable resistance layer, the exposed first interlayer insulating layer is exposed to the oxygen plasma and is thereby damaged. The damage of the interlayer insulating layer is particularly serious, for example, when the interlayer insulating layer is made of a low dielectric constant material (low-k material), since low dielectric constant materials are readily damaged compared to other materials.

A damaged layer increases the parasitic capacitance between the first conductive layer and the second conductive layer (e.g., between the upper and lower wirings). Such an increase in parasitic capacitance is serious, in particular, when the interlayer insulating layer is made of a low dielectric constant material, since low dielectric constant materials readily increase their dielectric constants particularly by damage, compared to other materials.

In view of the above-described findings, proposed is, for example, a process including steps of forming a sacrificial layer (corresponding to the first interlayer insulating layer) so as to cover the first conductive layer, forming a variable resistance element on the sacrificial layer, etching the sacrificial layer such that the sacrificial layer does not exist in a plan view, and then forming a homogeneous insulating layer continuously along the sides of the first contact, the variable resistance element, and the second contact.

In such a method, even if the surface of the sacrificial layer is damaged, the damaged layer is completely or mostly removed by etching, and then an insulating layer is anew formed. The risk of increasing the parasitic capacitance by the damaged layer lying between the first conductive layer and the second conductive layer is therefore reduced.

The explanation above merely relates to an embodiment and does not limit the scope of the present disclosure.

Embodiments of the present disclosure will now be described with reference to the attached drawings.

The embodiments described below are merely exemplary examples of the present disclosure. For example, the numerical values, shapes, materials, components, arrangement positions and connection configuration of the components, steps, and order of the steps shown in the following embodiments are merely exemplary examples and do not limit the present disclosure. Among the components in the following embodiments, components that are not mentioned in the independent claims describing the broadest concept of the present disclosure will be described as optional components. In the drawings, descriptions for components denoted by the same symbols may be omitted. The drawings schematically illustrate each component for easier understanding, and, for example, the shapes and sizes are not, therefore, exactly shown in some cases. In the method, the order of the steps can be optionally changed, and known steps may be additionally performed.

### DESCRIPTION OF TERMS

In the following embodiments, the term “oxygen content” refers to the ratio of the number of oxygen atoms to the total number of the atoms constituting a metal oxide.

The term “degree of oxygen deficit” refers to, in a metal oxide, the proportion of the amount of oxygen lacking relative to the amount of oxygen constituting the metal oxide in a stoichiometric composition (when a plurality of stoichiometric compositions are available, the stoichiometric composition having the highest resistance value).

The term “oxygen-deficient metal oxide” refers to a metal oxide having an oxygen content (the proportion of the number of oxygen atoms to the total number of atoms) less than that of the metal oxide in a stoichiometric composition.

The term “metal oxide in a stoichiometric composition” refers to a metal oxide having a degree of oxygen deficit of 0%. For example, the metal oxide in a stoichiometric composition of tantalum oxide refers to an insulator Ta₂O₅. Metal oxides gain electrical conductivity with deficiency of oxygen. An oxide having a small degree of oxygen deficit is nearer the oxide in the stoichiometric composition and therefore has a high resistance value, whereas an oxide having a large degree of oxygen deficit is nearer the metal constituting the oxide and therefore has a low resistance value. More specifically, when the metal is tantalum (Ta), the stoichiometric composition of the metal oxide is Ta₂O₅ and can be represented by TaO_{2.5}. The degree of oxygen deficit of TaO_{2.5} is 0%. For example, oxygen-deficient tantalum oxide having a composition of TaO_{1.5} has a degree of oxygen deficit: (2.5−1.5)/2.5=40%. Meanwhile, the oxygen content is represented by a ratio of the number of oxygen atoms to the total number of the atoms constituting the metal oxide, as described above. The oxygen content of Ta₂O₅ is the ratio (O/(Ta+O)) of the number of oxygen atoms to the total number of atoms: 71.4 atm %. The oxygen-deficient tantalum oxide, therefore, has an oxygen content of higher than 0 and lower than 71.4 atm %. When the metal constituting a first metal oxide and the metal constituting a second metal oxide are the same, the degrees of oxygen deficit of the metal oxides can be expressed by the oxygen contents. For example, if the first metal oxide has a degree of oxygen deficit larger than that of the second metal oxide, the first metal oxide has an oxygen content lower than that of the second metal oxide.

The term “insulator” follows the common definition. That is, the insulator is made of a material having a resistivity of 1×10⁸ Ω·cm or more (see “Syusekikairo no tameno Handotai Kogaku (Semiconductor engineering for integrated circuit)”, Kogyo Chosakai Publishing Co., Ltd. (1992), Akira USAMI, Shinji KANEBOU, Takao MAEKAWA, Hajime TOMOKAGE, Morio INOUE). In contrast, “conductor” is made of a material having a resistivity of lower than 1×10⁸ Ω·cm. Before execution of initial break-down behavior, the resistivity of a first metal oxide is different from that of a third metal oxide by 4 to 6 digits or more. After execution of initial break-down behavior, variable resistance element 10 has a resistivity of approximately 1×10⁴ Ω·cm.

The “standard electrode potential” is generally an indicator of ease of oxidation. A higher standard electrode potential means higher oxidation resistance, and a lower standard electrode potential means lower oxidation resistance. A larger difference in standard electrode potential between an electrode and a low-oxygen-deficient layer (second variable resistance layer) having a low degree of oxygen deficit readily causes a redox reaction and readily causes a resistance change. A decrease in difference of the standard electrode potential prevents the redox reaction and the resistance change. The ease of oxidation seems to be highly involved in the mechanism of resistance change phenomenon.

In the following embodiments, the vertical direction is defined such that the direction from the first electrode toward the second electrode is the “up” and that the direction from the second electrode toward the first electrode is the “down”. When a nonvolatile storage device includes a substrate, typically, the direction remote from the substrate is up, and the direction close to the substrate is down. The “upper surface” of the surfaces constituting a layer means the surface facing the second electrode side, whereas the “bottom surface” means the surface facing the first electrode side. These surfaces are not limited to flat surfaces and include curved surfaces.

### First Embodiment

The nonvolatile storage device in a first embodiment is a method for manufacturing the nonvolatile storage device, the method including: forming a first conductive layer on a substrate; forming a sacrificial layer covering the first conductive layer; forming a contact plug passing through the sacrificial layer to be the contact plug in contact with the first conductive layer, the contact plug including a conductive material; forming a variable resistance element covering the upper surface of the contact plug; removing the sacrificial layer other than a part of the sacrtificial layer that covers a sidewall of the contact plug; forming one single insulating layer that is directly or indirectly in contact with a side of the contact plug and that is directly or indirectly in contact with the variable resistance element; and forming a second conductive layer on the variable resistance element.

The etching of the sacrificial layer may remove the whole sacrificial layer or may remain a part of the sacrificial layer.

The term “continuously” means that the insulating layer along the side of the contact and the insulating layer along the side of the variable resistance element are continuously formed.

The nonvolatile storage device in the first embodiment includes; a first conductive layer disposed on a substrate; a contact plug including a conductive material and disposed on the first conductive layer; a variable resistance element that covers the upper surface of the contact plug, resistance of the variable resistance element changing in accordance with an voltage applied to the variable resistance element; one single insulating layer that is directly or indirectly in contact with a sidewall of the contact plug and that is directly or indirectly in contact with the variable resistance element; and a second conductive layer disposed on the variable resistance element.

In the first embodiment, occurrence of a damaged layer in the insulating layer can be prevented. As a result, the parasitic capacitance between the first conductive layer and the second conductive layer can be reduced. The electricity consumption necessary for the read/write operation of the nonvolatile storage device can be reduced than before, and the nonvolatile storage device can be operated at a high speed.

In the method of producing the nonvolatile storage device, at the removing of the sacrificial layer, an outer edge of the variable resistance element may be coincided with an outer edge of the sacrificial layer in a plan view.

The nonvolatile storage device may further include; a sacrificial layer that covers the sidewall of the contact plug between the variable resistance element and the first conductive layer, wherein an outer edge of the variable resistance element is coincided with an outer edge of the sacrificial layer in a plan view; and the one single insulating layer is in contact with a sidewall of the variable resistance element and the sidewall of the sacrificial layer.

In the nonvolatile storage device and the method for manufacturing the device described above, the one single insulating layer may have a relative dielectric constant of 2.2 or more and 3.0 or less.

In the nonvolatile storage device and the method for manufacturing the device described above, the one single insulating layer may have an average pore size of 2 nm or more and 6 nm or less.

In the nonvolatile storage device and the method for manufacturing the device described above, the one single insulating layer may have an carbon concentration of 10% or more and 30% or less as the atomic composition percentage.

Such a structure can reduce the parasitic capacitance between the first conductive layer and the second conductive layer and thereby can prevent the charge and discharge of the parasitic capacitance. Consequently, the electricity consumption necessary for the read/write operation of the nonvolatile storage device can be reduced than before, and the nonvolatile storage device can be operated at a high speed.

In the nonvolatile storage device and the method for manufacturing the device described above, the mechanical strength of the one single insulating layer may be lower than that of the sacrificial layer.

Such a structure can reduce the parasitic capacitance between the first conductive layer and the second conductive layer and can also prevent pattern peeling during the formation of the contact. As a result, a reduction in yield is prevented, and the reliability is improved.

In the nonvolatile storage device and the method for manufacturing the device described above, the variable resistance element may have a structure composed of a first electrode, a variable resistance layer, and a second electrode laminated in this order.

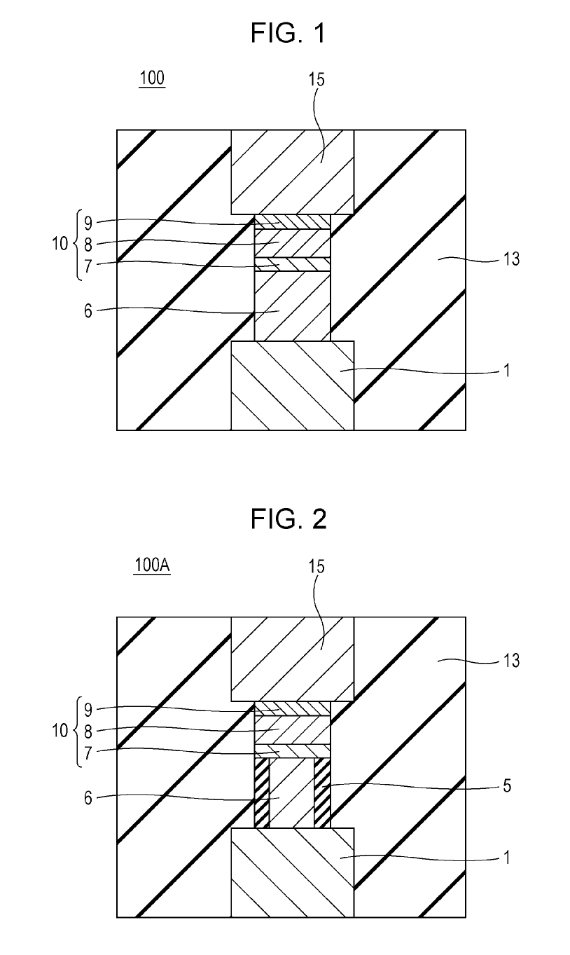

FIG. 1 is a cross-sectional view schematically illustrating an example of the configuration of a nonvolatile storage device according to the first embodiment. The nonvolatile storage device 100 of the first embodiment will now be described with reference to FIG. 1.

In the example shown in FIG. 1, the nonvolatile storage device 100 includes a first conductive layer 1, a contact 6, a variable resistance element 10, an insulating layer 13, and a second conductive layer 15.

The first conductive layer 1 is made of, for example, copper or aluminum. The first conductive layer 1 may function as, for example, a lower wiring.

The contact 6 may be disposed on the first conductive layer 1 and be connected to the first conductive layer 1. The contact 6 is made of, for example, tungsten.

The variable resistance element 10 is disposed so as to cover the contact 6. The variable resistance element 10 may partially cover the contact 6. The term “cover” means, for example, that the end face of the contact 6 in the extension direction is covered. In the example shown in FIG. 1, the variable resistance element 10 includes a first electrode 7, a variable resistance layer 8, and a second electrode 9. The variable resistance element 10 will be described in detail later.

The insulating layer 13 is a uniform layer continuously formed along the sides of the contact 6 and the variable resistance element 10. The insulating layer 13 is made of, for example, a low dielectric constant material (low-k material). The insulating layer 13 made of a low dielectric constant material can reduce the parasitic capacitance between the first conductive layer 1 and the second conductive layer 15. The dielectric constants of low dielectric constant materials are readily increased by damages caused by, in particular, etching, oxidation, oxygen plasma treatment, etc. In the configuration in the first embodiment, however, the damage of the insulating layer 13 can be reduced even if the insulating layer 13 is made of a low dielectric constant material, and the parasitic capacitance between the first conductive layer 1 and the second conductive layer 15 can be effectively reduced.

The insulating layer 13 preferably has a relative dielectric constant of 2.2 or more and 3.0 or less, an average pore diameter of 2 nm or more and 6 nm or less, and a carbon concentration of 10% or more and 30% or less as the atomic composition percentage. The material of the insulating layer 13 may contain at least one selected from the group consisting of SiOC and SiOCH. The insulating layer 13 preferably has a thickness of, for example, 100 nm or more and 500 nm or less.

In the description above, the “uniform” insulating layer means, for example, that the insulating layer does not contain a portion damaged by plasma treatment, oxidation, etching, etc. along the sides of the contact 6 and the variable resistance element 10. More specifically, for example, the uniform insulating layer is produced by a single and continuous process.

The “side of the contact 6” may be a part of the side of the contact 6.

The “side of the variable resistance element 10” may be a part of the side of the variable resistance element 10.

“Along the sides of the contact 6 and the variable resistance element 10” refers to, for example, a region from the height of the lower surface of the contact 6 to the height of the upper surface of the second electrode 9 constituting a part of the variable resistance element 10 including the sides of the interface between the contact 6 and the variable resistance element 10.

The second conductive layer 15 is disposed in the upper portion of the insulating layer 13 so as to cover the variable resistance element 10. The second conductive layer 15 may partially cover the variable resistance element 10. The second conductive layer 15 is made of, for example, copper or aluminum and may function as, for example, upper wiring.

The variable resistance element 10 is a nonvolatile storage element that reversibly changes the resistance value by, for example, application of an electrical pulse. The variable resistance element 10 may be, for example, a resistance random access memory (ReRAM). Alternatively, the variable resistance element 10 may be a phase change RAM (PRAM) utilizing phase change recording, a magnetoresistive random access memory (MRAM) utilizing magnetic recording, or a ferroelectric random access memory (FeRAM) using a ferroelectric substance.

The variable resistance element 10 may include a first electrode 7, a second electrode 9, and a variable resistance layer 8 of a metal oxide disposed between the first electrode 7 and the second electrode 9.

The first electrode 7 is made of, for example, tantalum nitride having a thickness of 50 to 200 nm. The first electrode 7 may be made of, for example, tungsten, nickel, tantalum, titanium, aluminum, or titanium nitride.

The metal oxide for the variable resistance layer 8 may be a transition metal oxide. When tantalum is used as the transition metal oxide, the first electrode 7 is preferably made of a material showing a standard electrode potential being equal to or lower than that of tantalum and scarcely causing resistance change. Specifically, the first electrode 7 may be made of at least one material selected from the group consisting of tantalum, tantalum nitride, titanium, titanium nitride, and titanium-aluminum nitride. Such a configuration can achieve stable memory characteristics.

The first electrode 7 may be physically connected to the contact 6 or may be connected to the contact 6 with a conductor therebetween. In FIG. 1, the first electrode 7 is directly connected to the contact 6. That is, the first electrode 7 is physically connected to the contact 6.

The variable resistance layer 8 is disposed between the first electrode 7 and the second electrode 9. The resistance value of the variable resistance layer 8 may be reversibly changed between a high-resistance state and a low-resistance state having a resistance value lower than that of the high-resistance state, based on, for example, electrical signals applied between the first electrode 7 and the second electrode 9.

In the example shown in FIG. 1, the variable resistance layer 8 is disposed between the first electrode 7 and the second electrode 9 and is made of oxygen-deficient tantalum oxide having a thickness of 5 nm or more and 50 nm or less. The variable resistance layer 8 may be made of, for example, a transition metal oxide, such as titanium oxide, nickel oxide, hafnium oxide, zirconium oxide, niobium oxide, or tungsten oxide; or aluminum oxide.

The variable resistance layer 8 may be a monolayer or may be composed of a plurality of layers having different oxygen contents. A variable resistance layer 8 composed of a plurality of layers may include at least two layers: a first variable resistance layer made of a first metal oxide and a second variable resistance layer made of a second material oxide having an oxygen content higher than that of the first metal oxide.

In other words, the variable resistance layer 8 may have a laminated structure composed of a first variable resistance layer and a second variable resistance layer. The first variable resistance layer is preferably made of oxygen-deficient tantalum oxide (TaOₓ, 0<x<2.5), and the second variable resistance layer is preferably made of tantalum oxide (TaO_{y}, x<y) having a degree of oxygen deficit lower than that of the first variable resistance layer.

The example described above is a case that both the first metal constituting the first metal oxide and the second metal constituting the second metal oxide are tantalum (Ta), but the metal is not limited thereto. The metals of the first metal oxide and the second metal oxide may be other metals. The metal oxides of different metals may be used as the first and second metal oxides.

The first metal oxide and the second metal oxide constituting the variable resistance layer 8 may each independently contain at least one selected from the group consisting of transition metal oxides and aluminum oxide. The first metal oxide and the second metal oxide constituting the variable resistance layer 8 may each independently contain at least one selected from the group consisting of tantalum oxides, hafnium oxide, and zirconium oxide.

The first metal and the second metal may be, instead of tantalum (Ta), for example, at least one transition metal selected from the group consisting of titanium (Ti), hafnium (Hf), zirconium (Zr), niobium (Nb), and tungsten (W). Since transition metals can have multiple oxidation states, different resistance states can be achieved by a redox reaction. The first metal and the second metal may be aluminum (Al).

The variable resistance layer 8 may have an oxidized region in the sidewall.

The variable resistance layer 8 may be composed of three or more layers.

The second electrode 9 is an electrode disposed above the first electrode 7. The second electrode 9 is disposed on the variable resistance layer 8. The second electrode 9 is made of a noble metal material, such as iridium, platinum, or palladium, and has a thickness of 5 nm or more and 100 nm or less. The second electrode 9 may be made of, for example, at least one material selected from the group consisting of iridium (Ir), platinum (Pt), and palladium (Pd), and preferably has a standard electrode potential higher than those of the metal constituting the second variable resistance layer of the variable resistance layer 8 and the first electrode material constituting the first electrode 7. Such a configuration causes a redox reaction selectively in a vicinity of the interface between the second electrode 9 and the second variable resistance layer to achieve a stable resistance change phenomenon.

In the nonvolatile storage device of the first embodiment, the parasitic capacitance is reduced by the damaged layer lying between the first conductive layer and the second conductive layer. Since the charge and discharge of the parasitic capacitance is prevented, the electricity consumption necessary for the read/write operation of the nonvolatile storage device can be reduced than before, and the nonvolatile storage device can be operated at a high speed.

In the nonvolatile storage device of the first embodiment, the insulating layer 13 is a homogeneous layer disposed along the sides of the contact 6 and the variable resistance element 10, which does not mean that the nonvolatile storage device of the first embodiment has no damaged layer between the first conductive layer and the second conductive layer. For example, the present disclosure encompasses an aspect where a damaged layer is locally formed in a part between the first conductive layer and the second conductive layer, even though the formation of the insulating layer along the side of the contact 6 and the formation of the insulating layer along the side of the variable resistance element 10 are continuously performed.

### Modification Example

FIG. 2 is a cross-sectional view schematically illustrating an example of the configuration of a nonvolatile storage device according to a modification example of the first embodiment. The nonvolatile storage device 100A of the modification example will now be described with reference to FIG. 2.

In the example shown in FIG. 2, the nonvolatile storage device 100A includes a sacrificial layer 5.

The sacrificial layer 5 is disposed between the variable resistance element 10 and the first conductive layer 1 so as to cover the first conductive layer 1. In the example shown FIG. 2, the sacrificial layer 5 is disposed on the first conductive layer 1 so as to cover a part of the first conductive layer 1. The sacrificial layer 5 is made of, for example, an insulating material. The sacrificial layer 5 may be made of a low dielectric constant material (low-k material) as in the insulating layer 13 or may be made of a material different from that of the insulating layer 13.

The sacrificial layer 5 may be made of a high dielectric constant material (high-k material). High dielectric constant materials have, for example, a relative dielectric constant of higher than 3.0. The sacrificial layer 5 may contain at least one selected from the group consisting of SiO₂, SiON, SiN, SiCN, FSG (fluorine (F)-doped SiO₂), and BPSG (boron (B)- and phosphorus (P)-doped SiO₂). The sacrificial layer 5 may be made of TEOS. Such a structure can reduce a risk of detachment of the variable resistance element 10 from the contact 6 and sacrificial layer 5.

The contact 6 passes through the sacrificial layer 5.

In a plan view, the outer edge of the variable resistance element 10 and the outer edge of the sacrificial layer 5 coincide with each other. The plan view is a view seen from, for example, the lamination direction of the first electrode 7, the variable resistance layer 8, and the second electrode 9 of the variable resistance element 10. The plan view is a view seen from, for example, the thickness direction of the substrate.

The insulating layer 13 is in physical contact with the variable resistance element 10 and the sacrificial layer 5.

The nonvolatile storage device 100A can have the same configuration as that of the nonvolatile storage device 100 of the first embodiment except for the points described above. Components common to FIGS. 1 and 2 are given the same reference numerals and names, and detailed descriptions thereof will be omitted.

### First Example

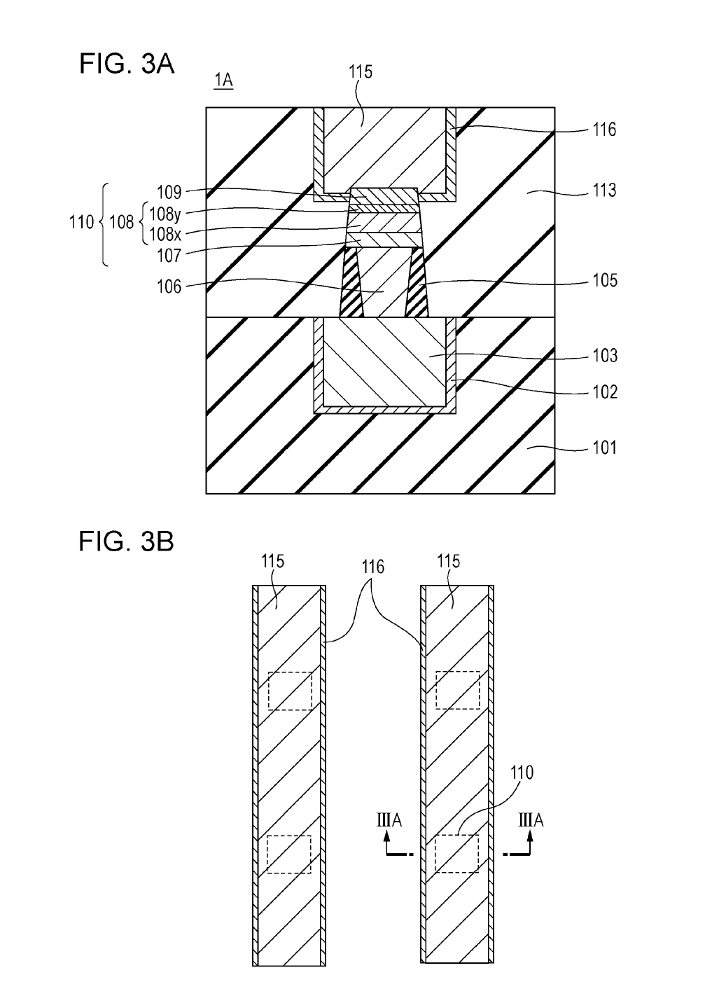

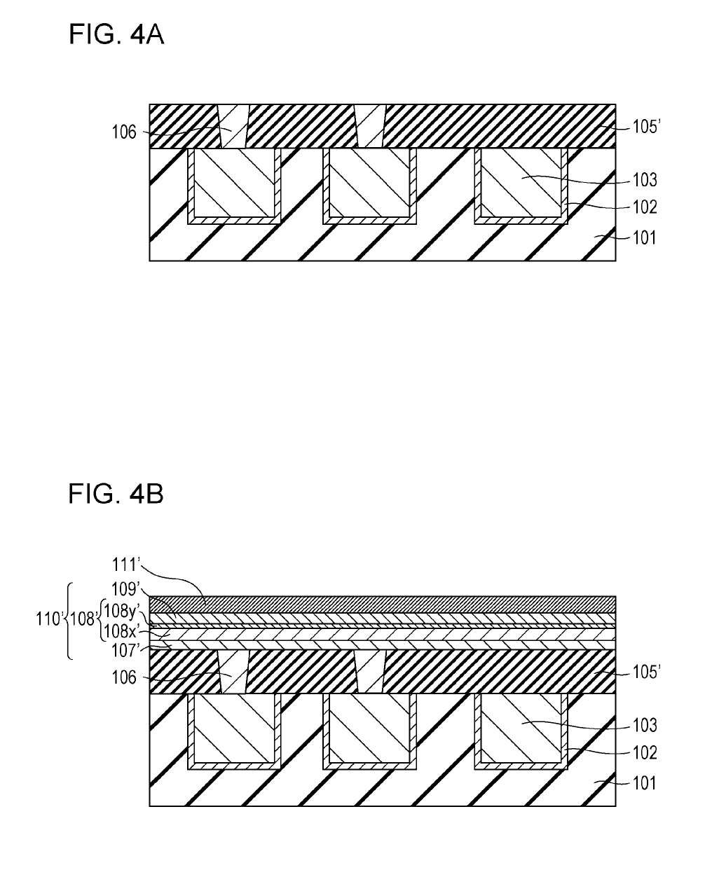

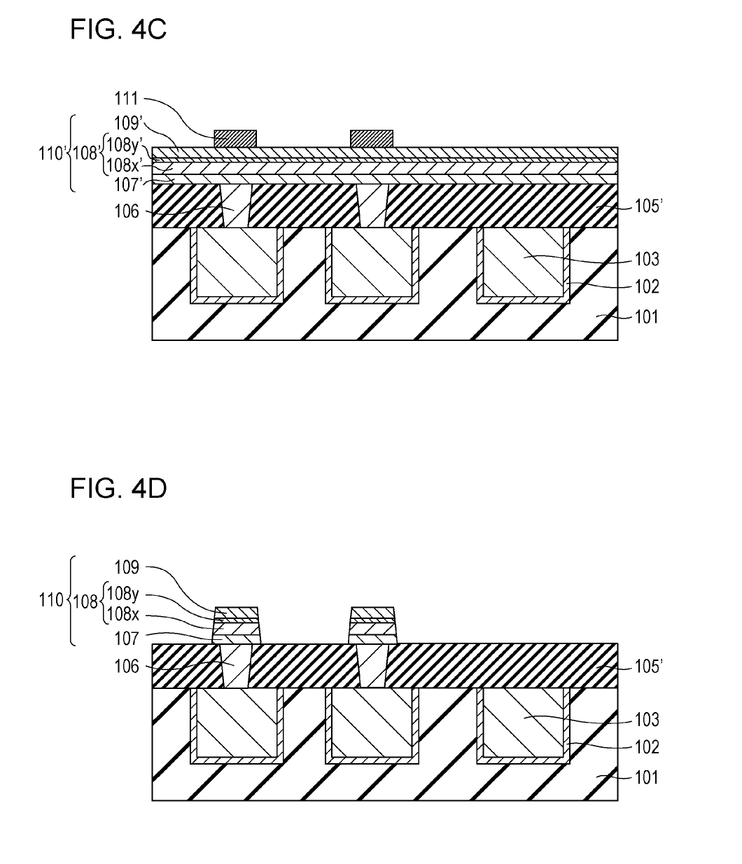

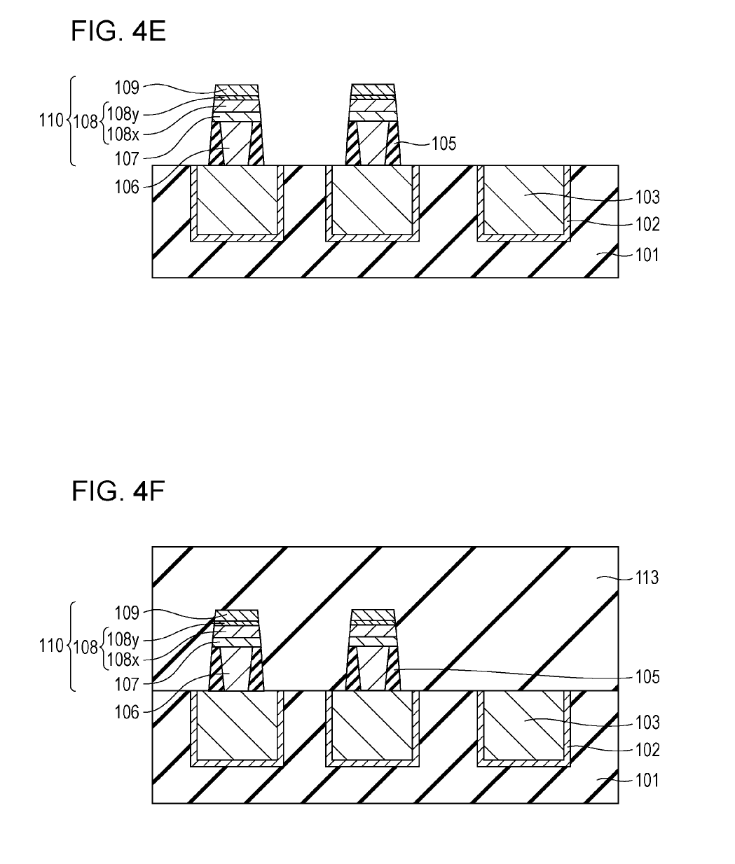

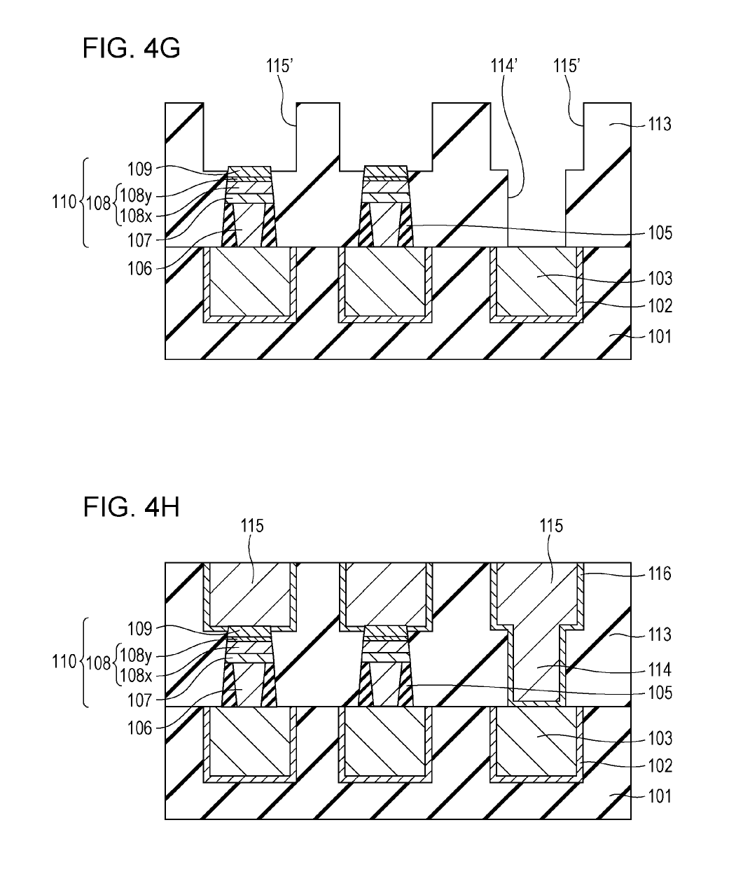

A first example will now be described with reference to FIGS. 3A, 3B, and 4A to 4H as an example of the nonvolatile storage device and the method of producing a nonvolatile storage unit of the nonvolatile memory devices according to a reference example of the first embodiment.

### Device Configuration

The configuration of the nonvolatile storage unit of the nonvolatile storage devices 1A according to the first example will be described with reference to FIGS. 3A and 3B. FIG. 3A is a cross-sectional view schematically illustrating the configuration of the nonvolatile storage device 1A according to the first example.

The nonvolatile storage device 1A shown in FIG. 3A is one memory cell of a memory cell array or memory body in a general semiconductor storage apparatus. FIG. 3B is a plan view of a part (composed of four memory cells as an example) of a memory cell array. FIG. 3A is a cross-sectional view from the direction of the arrows of line IIIA-IIIA in FIG. 3B. In FIG. 3B, the first conductive layer 103 and the first barrier metal layer 102 (not shown) are disposed directly below the second conductive layer 115 and the second barrier metal layer 116, respectively, in the same direction. Typically, a plurality of the nonvolatile storage devices 1A having the configuration shown in FIG. 3A forms a nonvolatile storage unit. Specifically, the nonvolatile storage unit includes a memory cell array composed of a plurality of the nonvolatile storage devices 1A, and may further include a driving circuit for driving the memory cell array.

In the following embodiments, their modification examples, and examples, the configuration of one nonvolatile storage device is shown for simplification of description. In the nonvolatile storage unit of each of the embodiments, their modification examples, and examples, however, a large number of nonvolatile storage devices are arrayed in rows and columns when viewed from the upper face as shown in the plan view of FIG. 3B, and these nonvolatile storage devices form a memory cell array.

The nonvolatile storage unit changes the resistance state of a desired variable resistance element 110 with an electric pulse for data storage supplied from the driving circuit to the memory cell array. The nonvolatile storage unit also reads out the resistance state of a desired variable resistance element 110 with an electric pulse for data reading supplied from the driving circuit to the memory cell array.

As shown in FIG. 3A, the nonvolatile storage device 1A includes a semiconductor substrate (not shown) provided with transistors and other components, a first insulating layer 101, a first conductive layer 103, a sacrificial layer 105, a contact 106, a variable resistance element 110, a second insulating layer 113, a second conductive layer 115, and a drawn contact 114 (not shown in FIG. 3A, see FIG. 4H).

The first insulating layer 101 is disposed on the semiconductor substrate (not shown) provided with transistors and other components.

The first insulating layer 101 may have a thickness of, for example, 20 nm or more and 500 nm or less. The first insulating layer 101 may have a porous structure including a large number of pores having a relative dielectric constant of approximately that of vacuum. The first insulating layer 101 can be a carbon-added silicon oxide (SiOC) film. The first insulating layer 101 may be an intermediate insulating film, such as a fluorine-added silicon oxide (SiOF) film, instead of the carbon-added silicon oxide (SiOC) film.

The average size of the pores in the first insulating layer 101 can be calculated from the size distribution of the pores measured by small angle X-Ray scattering (SAXS). The pores have, for example, a pore diameter of approximately 2 nm or more and 6 nm or less.

The first insulating layer 101 preferably has a carbon concentration of approximately 10% or more and 30% or less as the atomic composition percentage, measured by auger electron spectroscopy (AES). The first insulating layer 101 preferably has a relative dielectric constant of 2.2 or more and 3.0 or less.

The first conductive layer 103 is disposed on the inside of the first barrier metal layer 102 in the first insulating layer 101. In the first example, the first conductive layer 103 is made of copper, and the first barrier metal layer 102 has a laminated structure composed of a tantalum nitride film (thickness: 5 to 40 nm) and a tantalum film (thickness: 5 to 40 nm). The first conductive layer 103 may be made of another metal (e.g., aluminum), instead of copper.

The sacrificial layer 105 is disposed on the first conductive layer 103 and below the variable resistance element 110. In the first example, the sacrificial layer 105 is made of silicon oxide.

The contact 106 (diameter: 50 to 200 nm) is disposed on the inside of the sacrificial layer 105 and is electrically connected to the first conductive layer 103. The contact 106 may protrude from the region defined by the lower surface of the variable resistance element due to a misalignment of the mask.

The variable resistance element 110 is disposed on the sacrificial layer 105 and is connected to the contact 106. In other words, the variable resistance element 110 is disposed on the sacrificial layer 105 and the contact 106. The variable resistance element 110 includes a first electrode 107, a variable resistance layer 108, and a second electrode 109.

The first electrode 107 in the first example is made of tantalum nitride (thickness: 10 to 200 nm).

The variable resistance layer 108 in the first example is disposed between the first electrode 107 and the second electrode 109, is made of oxygen-deficient tantalum oxide, and has a thickness of 10 to 100 nm. The variable resistance layer 108 in the first example has a laminated structure composed of a first variable resistance layer 108x and a second variable resistance layer 108y. The first variable resistance layer 108x is made of oxygen-deficient tantalum oxide (TaOₓ, 0<x<2.5), and the second variable resistance layer 108y is made of tantalum oxide (TaO_{y}, x<y) having a degree of oxygen deficit lower than that of the first variable resistance layer 108x.

The variable resistance layer 108 reversibly changes its resistance state between a high-resistance state and a low-resistance state having a resistance value lower than that of the high-resistance state based on the electrical signals applied between the first electrode 107 and the second electrode 109.

The second electrode 109 in the first example will be described with an example using iridium (Ir). The material of the second electrode may be platinum (Pt), palladium (Pd), copper (Cu), or tungsten (W), instead of iridium (Ir).

The second insulating layer 113 is disposed on the first insulating layer 101. In the first example, the second insulating layer 113 is made of SiOC and has a thickness of 100 to 500 nm. The second insulating layer 113 may be an intermediate insulating film, such as a fluorine-added silicon oxide (SiOF) film, instead of the carbon-added silicon oxide (SiOC) film. The second insulating layer 113 may have a porous structure including a large number of pores having a relative dielectric constant of approximately that of vacuum. The second insulating layer 113 is a carbon-added silicon oxide (SiOC) film.

The average size of the pores in the second insulating layer 113 can be calculated from the size distribution of the pores measured by small angle X-Ray scattering (SAXS). The pores have, for example, a pore diameter of approximately 2 nm or more and 6 nm or less.

The second insulating layer 113 preferably has a carbon concentration of approximately 10% or more and 30% or less as the atomic composition percentage, measured by auger electron spectroscopy (AES). The second insulating layer 113 preferably has a relative dielectric constant of 2.2 or more and 3.0 or less.

The second conductive layer 115 is disposed on the inside of the second insulating layer 113. The second conductive layer 115 is connected to the second electrode 109 via the second barrier metal layer 116 made of a conductive material. In the first example, the second conductive layer 115 is made of copper, and the second barrier metal layer 116 has a laminated structure composed of tantalum nitride (thickness: 5 to 40 nm) and tantalum (thickness: 5 to 40 nm). The second conductive layer 115 may be made of another metal (e.g., aluminum), instead of copper.

Throughout the specification, conductive layers that are connected to the respective nonvolatile storage elements are called “wiring”, and a single conductive layer that is connected to the corresponding single nonvolatile storage element is called “via”. That is, in the specification, the term “conductive layer” includes wiring and via.

### Method of Production

A method of producing a nonvolatile storage unit of the nonvolatile storage devices 1A according to the first example will be described with reference to FIGS. 4A to 4H.

FIGS. 4A to 4H are cross-sectional views illustrating the structure of the main part in each step of the method of producing a nonvolatile storage unit of the nonvolatile storage devices 1A of the first example.

As shown in FIG. 4A, a first insulating layer 101 is formed on a semiconductor substrate (not shown) previously provided with transistors and other components. Subsequently, first conductive layers 103 are formed in the first insulating layer 101, and contacts 106 are formed on the respective first conductive layers 103 and are connected to the first conductive layers 103.

Specifically, a SiOC-based silicon oxide film is formed on the semiconductor substrate by plasma CVD using a raw material mixture of trimethylsilane and/or tetramethylsilane and an organic compound having a cyclic molecular structure containing Si—O bonds (e.g., circular siloxane), so-called porogen. The resulting film is irradiated with ultraviolet rays to form a first insulating layer 101.

Subsequently, grooves for burying first conductive layers 103 are formed in the first insulating layer 101 by photolithography and dry etching. In each of the grooves, a first barrier metal layer 102 (e.g., a laminated structure composed of tantalum nitride (thickness: 5 to 40 nm) and tantalum (thickness: 5 to 40 nm)) and a seed layer of copper as a wiring material (thickness: 50 to 300 nm) are deposited by sputtering. Copper is then further deposited on the seed layer of copper by, for example, electroplating to fill the entire groove with copper as a wiring material. The extra deposited copper on the surface is then removed by chemical mechanical polishing (CMP) to planarize the surface of the first insulating layer 101 and the surfaces of the first conductive layers 103. Thus, each first conductive layer 103 is formed.

A sacrificial material layer 105′ is then deposited on the first conductive layers 103. The surface is optionally subjected to CMP for reducing its unevenness.

Contact holes are then formed on predetermined positions of the respective first conductive layers 103 by photolithography and dry etching such that the contact holes pass through the sacrificial material layer 105′ and that the first conductive layers 103 are exposed. The contact holes in the first example have a core size of 50 to 300 nm.

If the first conductive layer 103 has a width smaller than the diameter of the contact hole, a misalignment of the mask may cause a difference in the area where the first conductive layer 103 and the contact 106 are in contact with each other between the variable resistance elements, leading to a risk of a fluctuation in cell current. From the viewpoint of preventing such a fluctuation, the first conductive layer 103 preferably has a width larger than the diameter of the contact hole.

The contact holes are then filled with a material for forming contacts 106. Specifically, titanium nitride (TiN) and titanium (Ti) are deposited by sputtering to form a lamination of a thickness of 5 to 30 nm to form a lower layer functioning as an adhesion layer and a diffusion barrier. An upper layer is then formed on the lower layer by depositing tungsten by CVD to a thickness of 200 to 400 nm. As a result, the contact holes are filled with a filler mainly composed of tungsten. The entire surface is then polished for planarization by chemical mechanical polishing (CMP) to remove the unnecessary filler on the sacrificial layer 105. Thus, a contact 16 is formed inside each of the contact holes.

Subsequently, as shown in FIGS. 4B to 4D, a variable resistance element 110 is formed on the upper surface of each contact 106.

As shown in FIG. 4B, a first electrode material layer 107′, a variable resistance material layer 108′, a second electrode material layer 109′, and a hard mask film 111′ are deposited in this order on the sacrificial material layer 105′ including the contacts 106. The first electrode material layer 107′, preferably, has a thickness of 20 nm and is made of tantalum nitride. The variable resistance material layer 108′, preferably, has a thickness of 25 nm and is made of oxygen-deficient tantalum oxide. The second electrode material layer 109′, preferably, contains iridium and has a thickness of 40 nm. The hard mask film 111′ is preferably made of titanium-aluminum nitride and is a conductive layer to be used as a hard mask for dry etching.

In the first example, the first electrode material layer 107′, the second electrode material layer 109′, and the hard mask film 111′ are deposited by sputtering.

The variable resistance material layer 108′ is formed through reactive sputtering by sputtering a target of tantalum in an argon and oxygen gas atmosphere. The oxygen concentration in the layer is adjusted to 45 to 65 atom % by controlling the oxygen flow rate. As a result, the first variable resistance material layer 108x′ can have a resistivity of 0.5 to 20 mΩ·cm. The first variable resistance material layer 108x′ is further oxidized to form a second variable resistance material layer 108y′ (Ta₂O₅ layer, thickness: 2 to 12 nm) having an oxygen content higher than that of the first variable resistance material layer 108x′ on the outermost surface of the oxygen-deficient first variable resistance material layer 108x′.

Subsequently, as shown in FIG. 4C, the hard mask film 111′ is patterned into island-like shapes independent of one another by photolithography and dry etching to form hard masks 111. The hard masks 111 each have a side length of 50 to 400 nm, for example, a side length of 100 nm.

Subsequently, as shown in FIG. 4D, dry etching is performed using the patterned hard masks 111 to form variable resistance elements 110 each consisting of the horizontally laminated first electrode 107, the variable resistance layer 108, and the second electrode 109. That is, the dry etching gives variable resistance elements 110 in island-like shapes (side length: 50 to 400 nm) that are disposed apart from one another and are connected to the respective contacts 106.

It is difficult to use a high vapor pressure of gaseous species for dry etching of a noble metal, such as iridium or platinum. When a noble metal, such as iridium or platinum, is used as a material for the second electrode 109 as in the first example, the second electrode 109 has a trapezoidal vertical cross-section having a taper angle of less than 90°.

The shape of the second electrode 109 is reflected to the first electrode 107 and the variable resistance layer 108 lying below the second electrode 109, and they also each have a trapezoidal vertical cross-section having a taper angle of less than 90°.

After the formation of the variable resistance elements 110 by dry etching, the hard masks 111 on the second electrodes 109 may be removed or may be retained.

Subsequently, as shown in FIG. 4E, the sacrificial material layer 105′ is dry-etched until the first insulating layer 101 is exposed using the second electrodes 109 of the variable resistance elements 110 or the hard masks 111 as the mask. Thus, sacrificial layers 105 are formed.

As shown in FIGS. 4F to 4H, second conductive layers 115 are then formed on the inside of the second insulating layer 113 and on the respective variable resistance elements 110 so as to be in physical contact with the respective second electrodes 109.

First, as shown in FIG. 4F, a second insulating layer 113 is deposited on the variable resistance elements 110 and the sacrificial layers 105 (so as to also cover the sides thereof). The second insulating layer 113 may be deposited by the same process and the same conditions as those for the formation of the first insulating layer 101.

Subsequently, as shown in FIG. 4G, grooves 115′ and a contact hole 114′ are formed in the second insulating layer 113 by photolithography and dry etching. The grooves 115′ are formed such that the second electrodes 109 are exposed. The contact hole 114′ is formed at a predetermined position where no variable resistance element 110 is disposed on the first conductive layer 103.

In general, the contact hole 114′ is previously formed by first photolithography and dry etching, and the grooves 115′ are then formed by second photolithography and dry etching. Alternatively, the grooves 115′ may be previously formed.

Subsequently, as shown in FIG. 4H, second conductive layers 115 are formed as in the formation of the first conductive layers 103: A second barrier metal layer 116 and a seed layer of copper (thickness: 50 to 300 nm) are deposited by sputtering in each of the contact hole 114′ and the grooves 115′. The second barrier metal layer 116 may have a laminated structure composed of, for example, tantalum nitride (thickness: 5 to 40 nm) and tantalum (thickness: 5 to 40 nm). Copper is then further deposited using copper of the seed layer as a seed by, for example, electroplating to fill the entire grooves 115′ with copper as a wiring material. The extra copper on the surface and the second barrier metal layers 116 are then removed by CMP to planarize the surface of the second insulating layer 113 and the surfaces of the second conductive layers 115. Thus, each second conductive layer 115 is formed.

As described above, the configuration and the method of the first example can prevent formation of a damaged layer in the second insulating layer. As a result, an increase in parasitic capacitance can be inhibited, and charge and discharge of parasitic capacitance can be prevented. The electricity consumption necessary for the read/write operation of the nonvolatile storage device can be, therefore, reduced than before, and the nonvolatile storage unit can be operated at a high speed.

The first example can also be modified as in the first embodiment and its modification examples.

### Second Embodiment

The nonvolatile storage device in a second embodiment is different from that of the first embodiment in that a diffusion-preventing layer is disposed on the first conductive layer.

The method for manufacturing a nonvolatile storage device of the second embodiment is different from that of the first embodiment in that a diffusion-preventing layer covering at least an upper surface of the first conductive layer is further formed before the forming of the sacrificial layer and that the contact plug is formed so as to pass through the sacrificial layer and the diffusion-preventing layer to be the contact plug in contact with the first conductive layer.

The nonvolatile storage device of the second embodiment further includes, in addition to the components of the nonvolatile storage device of the first embodiment, a diffusion-preventing layer covering at least an upper surface of the first conductive layer, where the contact plug passes through the diffusion-preventing layer to be the contact plug in contact with the first conductive layer.

In such a configuration, for example, the first conductive layer can be prevented from being exposed to the etching gas during the etching for forming the variable resistance element 10. As a result, diffusion and damage of the conductive layer in the post process (the steps after the formation of the variable resistance element 10 by etching) can be prevented. Consequently, electrical defects are reduced; a reduction in yield can be prevented; and the reliability is improved.

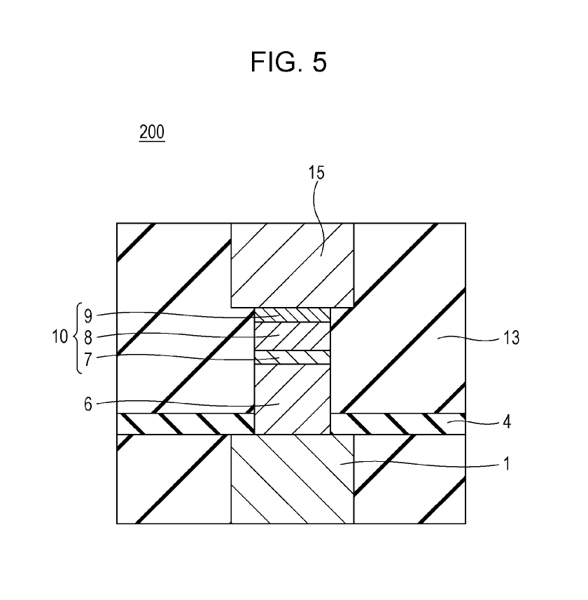

FIG. 5 is a cross-sectional view schematically illustrating an example of the configuration of a nonvolatile storage device according to the second embodiment. The nonvolatile storage device 200 of the second embodiment will now be described with reference to FIG. 5.

In the example shown in FIG. 5, the nonvolatile storage device 200 includes a diffusion-preventing layer 4.

The diffusion-preventing layer 4 covers the first conductive layer 1. The diffusion-preventing layer 4 is made of, for example, a silicon nitride or another nitride (e.g., SiCN). The diffusion-preventing layer 4 of such a nitride preferably has a thickness of 30 to 200 nm.

The contact 6 passes through the diffusion-preventing layer 4 and is in physical contact with the first conductive layer 1.

The nonvolatile storage device 200 has the same configuration as that of the nonvolatile storage device 100 of the first embodiment except for the points described above. The components common to FIGS. 1 and 5 are, therefore, given the same reference numerals and names, and detailed descriptions thereof will be omitted.

The second embodiment can also be modified as in the first embodiment and its modification examples.

### Second Example

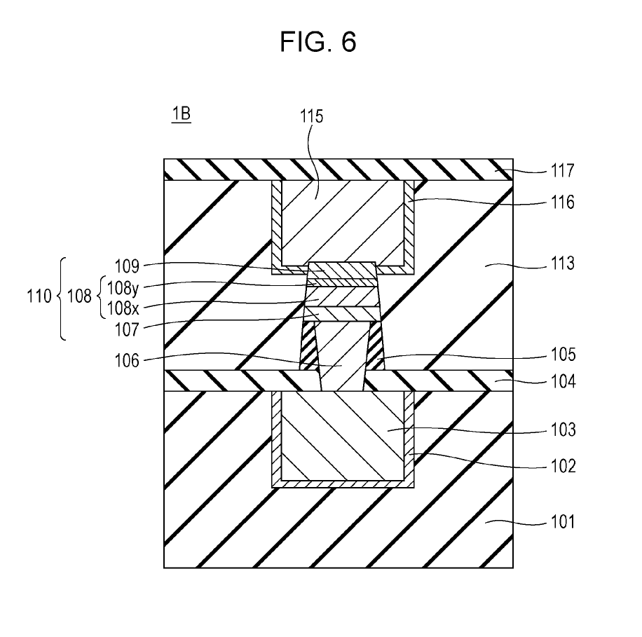

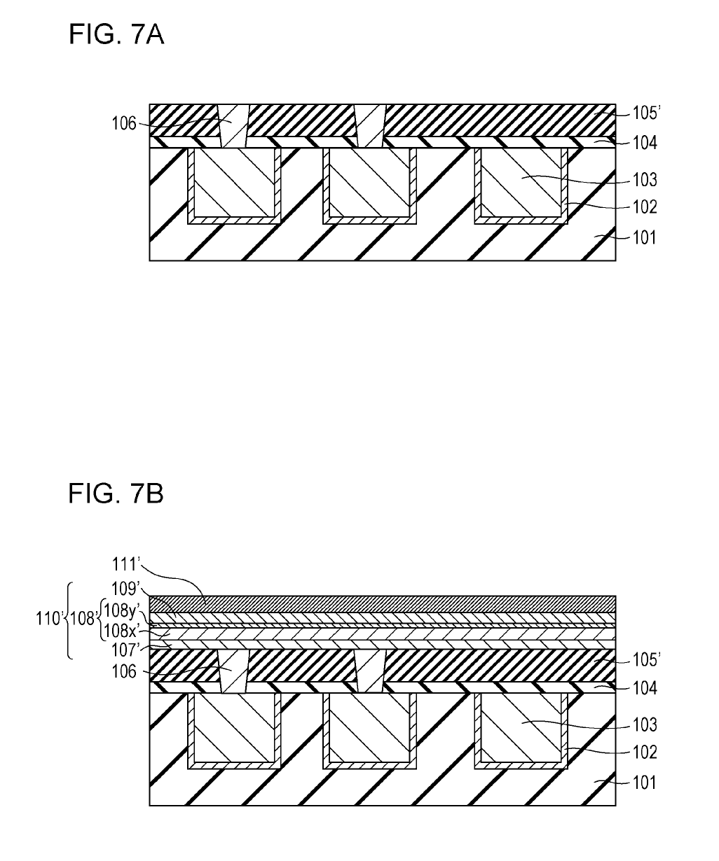

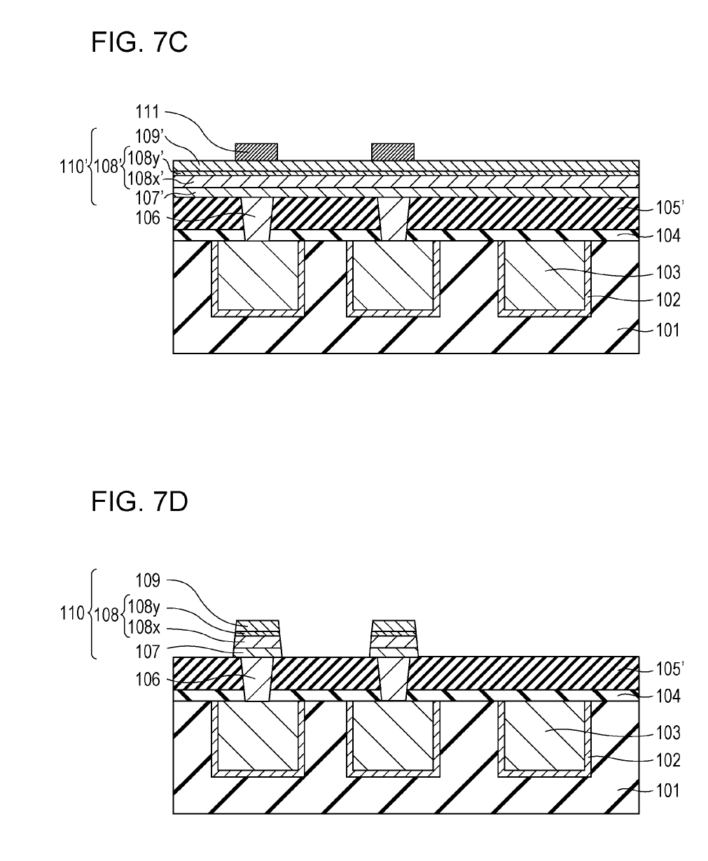

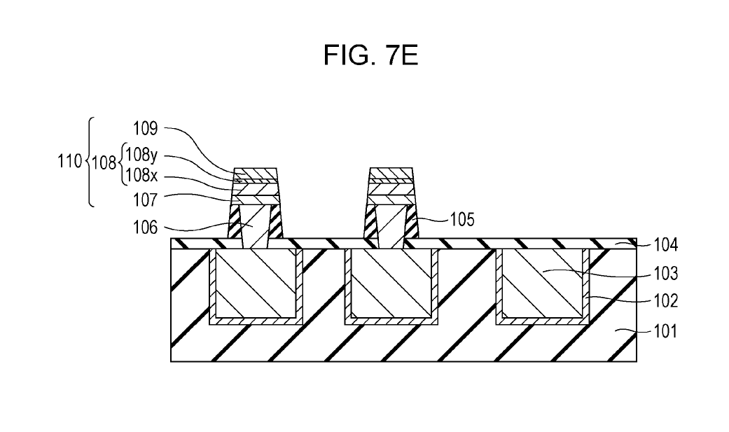

A second example will now be described with reference to FIGS. 6 and 7A to 7E as an example of the nonvolatile storage device and the method of producing a nonvolatile storage unit of the nonvolatile storage devices according to the second embodiment.

The nonvolatile storage device 1B of the second example is different from the nonvolatile storage device 1A of the first example in that a first diffusion-preventing layer 104 and a second diffusion-preventing layer 117 are disposed above the first conductive layer 103.

### Device Configuration

The configuration of the nonvolatile storage device 1B will be described with reference to FIG. 6. FIG. 6 is a cross-sectional view schematically illustrating the configuration of the nonvolatile storage device 1B according to the second example. The nonvolatile storage device 1B shown in FIG. 6 is one memory cell of a memory cell array or memory body of a general semiconductor storage apparatus.

That is, the nonvolatile storage unit includes a plurality of the nonvolatile storage devices 1B shown in FIG. 6. Specifically, the nonvolatile storage unit includes a memory cell array composed of a plurality of the nonvolatile storage devices 1B, and may further include a driving circuit for driving the memory cell array.

As shown in FIG. 6, the nonvolatile storage device 1B includes a first diffusion-preventing layer 104 and a second diffusion-preventing layer 117.

The first diffusion-preventing layer 104 covers the first insulating layer 101 and the first conductive layer 103. The contact 106 passes through the first diffusion-preventing layer 104 and the sacrificial layer 105 and is connected to the first conductive layer 103. The second insulating layer 113 is disposed on the first diffusion-preventing layer 104. The second diffusion-preventing layer 117 covers the second insulating layer 113 and the second conductive layer 115.

The first diffusion-preventing layer 104 and the second diffusion-preventing layer 117 in the second example are made of silicon nitride and have a thickness of 30 to 200 nm. The first diffusion-preventing layer 104 and the second diffusion-preventing layer 117 may be each made of, for example, another nitride (e.g., SiCN), instead of silicon nitride.

The nonvolatile storage device 1B of the second example has the same configuration as that of the nonvolatile storage device 1A of the first example except for the points described above. The components common to FIGS. 3A and 6 are, therefore, given the same reference numerals and names, and detailed descriptions thereof will be omitted.

### Method of Production

An example of the method of producing a nonvolatile storage unit of the nonvolatile storage devices 1B in the second example will be described with reference to FIGS. 7A to 7E.

FIG. 7E shows a step of dry-etching the sacrificial material layer 105′ until the first diffusion-preventing layer 104 is exposed. The subsequent steps after this step are the same as those shown in FIGS. 4F to 4H, and the descriptions thereof are omitted.

The method of the second example is different from that of the first example in that a first diffusion-preventing layer 104 and a second diffusion-preventing layer 117 are formed.

As shown in FIG. 7A, a first insulating layer 101 is formed on a semiconductor substrate (not shown) previously provided with transistors and other components. Subsequently, first conductive layers 103 are formed in the first insulating layer 101. This step is the same as that described in the first example, and the description thereof is omitted.

Subsequently, a first diffusion-preventing layer 104 covering the first insulating layer 101 and the first conductive layers 103 is formed by depositing silicon nitride to a thickness of approximately 30 to 200 nm by plasma CVD.

A sacrificial material layer 105′ is then deposited on the first diffusion-preventing layer 104. The surface is optionally subjected to CMP for reducing its unevenness.

Contact holes are then formed by removing the sacrificial material layer 105′ and the first diffusion-preventing layer 104 on predetermined positions of the respective first conductive layers 103 by photolithography and dry etching such that the contact holes pass through the sacrificial material layer 105′ and the first diffusion-preventing layer 104 and that the first conductive layers 103 are exposed. The contact holes in the second example have a core size of 50 to 300 nm.

If the first conductive layer 103 has a width smaller than the diameter of the contact hole, a risk of a fluctuation in cell current is caused as described in the first example. The first conductive layer 103, therefore, preferably has a width larger than the diameter of the contact hole.

Contacts 106 are then formed by the same procedure as that in the first example, and the description thereof is omitted.

Subsequently, as shown in FIGS. 7B to 7D, variable resistance elements 110 are formed on the respective contacts 106. The steps shown in FIGS. 7B to 7D are the same as those in the first example shown in FIGS. 4B to 4D, and the detailed descriptions thereof are omitted.

As shown in FIG. 7E, the sacrificial material layer 105′ is dry-etched until the first diffusion-preventing layer 104 is exposed using the second electrodes 109 of the variable resistance elements 110 or the hard masks 111 disposed on the second electrodes 109 as the mask. Thus, sacrificial layers 105 are formed.

In the second example, the sacrificial material layer 105′ made of silicon oxide is dry-etched, for example, at a chamber pressure of 2.1 Pa using etching gases, C₅F₈, O₂, and Ar, at flow rates of 17 sccm, 23 sccm, and 500 sccm, respectively. In this case, the etching rate of silicon nitride is low, 1/20 of that of silicon oxide. The first diffusion-preventing layer 104 is, therefore, hardly etched. That is, the first diffusion-preventing layer 104 functions as an etching stopper layer.

Subsequently, a second insulating layer 113 and second conductive layers 115 are formed, and a silicon nitride layer having a thickness of 30 to 200 nm (e.g., 50 nm) is formed through deposition by plasma CVD. Thus, a second diffusion-preventing layer 117 covering the second conductive layer 115 and the second insulating layer 113 is formed.

In the second example, the first conductive layer 103 can be prevented from being exposed during etching of the sacrificial material layer. As a result, diffusion and damage of the conductive layer in the post process can be prevented. Consequently, electrical defects are reduced; a reduction in yield can be prevented; and the reliability is improved.

The second example can also be modified as in the first and second embodiments and their modification examples.

### Third Embodiment

The nonvolatile storage device of a third embodiment is different from that of the first embodiment in that a sidewall protective layer is disposed on the sidewall of the variable resistance element.

The method for manufacturing a nonvolatile storage device of the third embodiment is different from that of the first embodiment in that a sidewall protective layer of an insulating material covering the sidewall of the variable resistance element is further formed after the forming of the variable resistance element and before the removing of the sacrificial layer, and that at the removing of the sacrificial layer, an outer edge of the sidewall protective layer is coincided with an outer edge of the sacrificial layer in a plan view.

The nonvolatile storage device of the third embodiment further includes; a sidewall protective layer including an insulating material and covering a sidewall of the variable resistance element; a sacrificial layer that covers the sidewall of the contact plug between the variable resistance element and the first conductive layer and between the sidewall protective layer and the first conductive layer. An outer edge of the sidewall protective layer is coincided with an outer edge of the sacrificial layer in a plan view. The one single insulating layer is in contact with the sidewall protective layer and the sacrificial layer.

In this configuration, the sidewall of the variable resistance element is covered with the sidewall protective layer. As a result, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

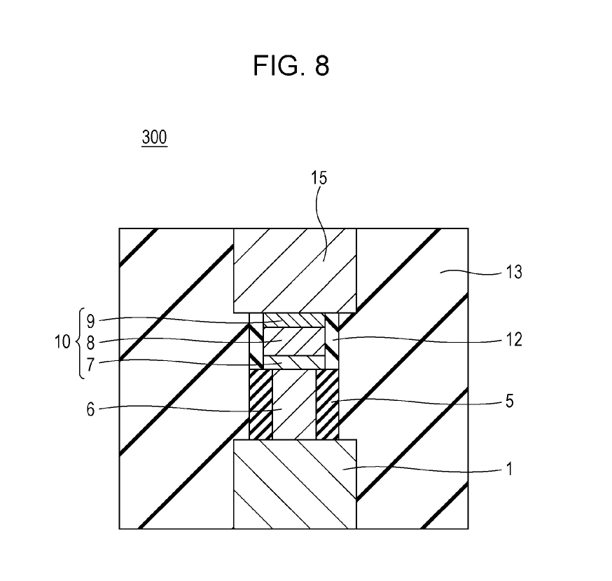

FIG. 8 is a cross-sectional view schematically illustrating an example of the configuration of a nonvolatile storage device according to the third embodiment. The nonvolatile storage device 300 will now be described with reference to FIG. 8.

The nonvolatile storage device 300 shown in FIG. 8 includes a sidewall protective layer 12. The sidewall protective layer 12 is made of an insulating material and covers the sidewall of the variable resistance element 10. The sidewall protective layer 12 may be formed so as to cover at least a part of the sidewall of the variable resistance element 10.

The sacrificial layer 5 is disposed between the variable resistance element 10 and the first conductive layer 1 and between the sidewall protective layer 12 and the first conductive layer 1 on the first conductive layer 1. The contact 6 passes through the sacrificial layer 5 and is in contact with the first conductive layer 1.

The outer edge of the sidewall protective layer 12 and the outer edge of the sacrificial layer 5 coincide with each other in a plan view. The insulating layer 13 is in physical contact with the sidewall protective layer 12 and the sacrificial layer 5.

The nonvolatile storage device 300 can have the same configuration as that of the nonvolatile storage device 100A, which is a modification example of the first example, except for the points described above. The components common to FIGS. 2 and 8 are, therefore, given the same reference numerals and names, and detailed descriptions thereof will be omitted.

The third embodiment can also be modified as in the first and second embodiments and their modification examples.

### Third Example

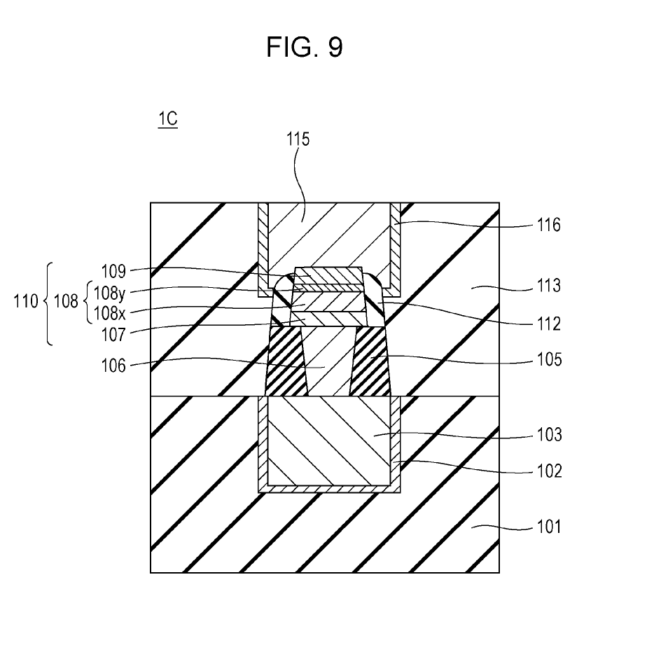

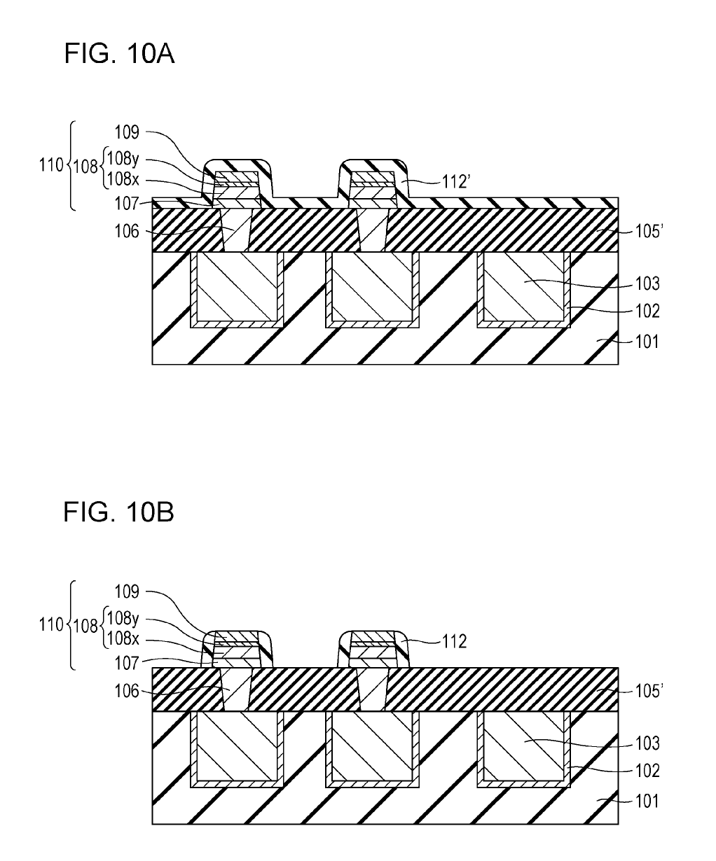

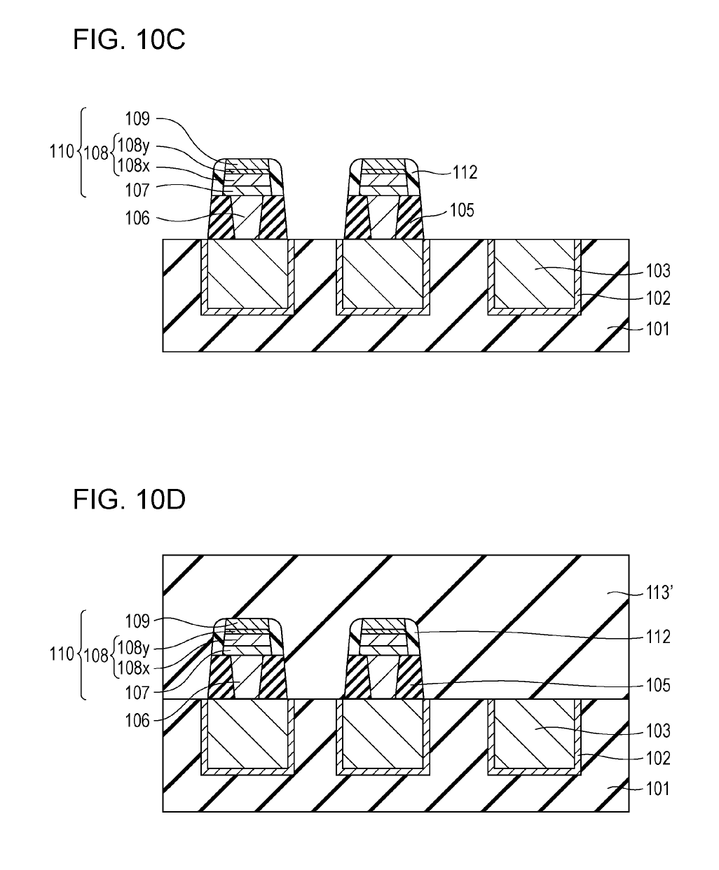

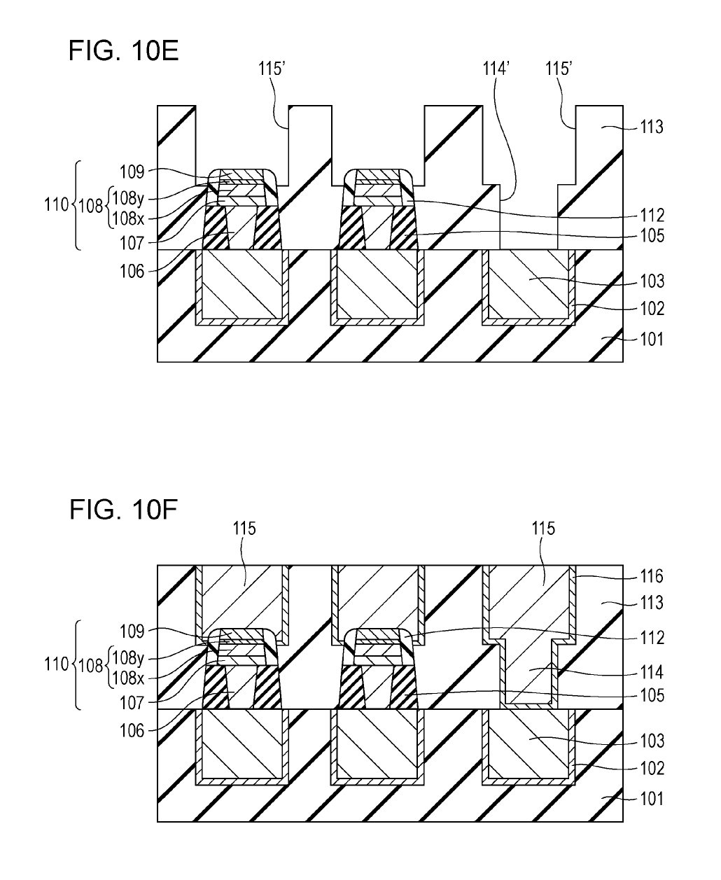

A third example will now be described with reference to FIGS. 9 and 10A to 10F as an example of the nonvolatile storage device 1C and the method of producing a nonvolatile storage unit of the nonvolatile storage devices 1C according to the third embodiment.

The nonvolatile storage device 1C of the third example is different from the nonvolatile storage device 1A of the first example in that a sidewall protective layer 112 is disposed on the sidewall of the variable resistance element 110.

### Device Configuration

The configuration of the nonvolatile storage device 1C will be described with reference to FIG. 9. FIG. 9 is a cross-sectional view illustrating an example of the configuration of the nonvolatile storage device 1C according to the third example. The nonvolatile storage device 1C shown in FIG. 9 is one memory cell of a memory cell array or memory body of a general semiconductor storage apparatus.

That is, the nonvolatile storage unit includes a plurality of the nonvolatile storage devices 1C shown in FIG. 9. Specifically, the nonvolatile storage unit includes a memory cell array composed of a plurality of the nonvolatile storage devices 1C, and may further include a driving circuit for driving the memory cell array.

As shown in FIG. 9, the nonvolatile storage device 1C includes a sidewall protective layer 112. The sidewall protective layer 112 covers the sidewall of the variable resistance element 110. The sidewall protective layer 112 is made of an insulating material. The sidewall protective layer 112 in the third example is made of silicon nitride and has a thickness of 10 to 50 nm. The sidewall protective layer 112 covers the sidewall of the variable resistance element 110 and is disposed on the sacrificial layer 105. The sidewall protective layer 112 may be made of an oxide (e.g., TiOₓ or AlOₓ), a nitride (e.g., AlN or TiN), or an oxynitride (e.g., SiON), instead of silicon nitride.

The lower surface of the first electrode 107 and the lower surface of the sidewall protective layer 112 lie in the same plane. The sacrificial layer 105 is disposed between the first electrode 107 and the first conductive layer 103 and between the sidewall protective layer 112 and the first conductive layer 103.

The nonvolatile storage device 1C of the third example has the same configuration as that of the nonvolatile storage device 1A of the first example except for the points described above. The components common to FIGS. 3A and 9 are, therefore, given the same reference numerals and names, and detailed descriptions thereof will be omitted.

### Method of Production

An example of the method of producing a nonvolatile storage unit of the nonvolatile storage devices 1C in the third example will be described with reference to FIGS. 10A to 10F.

The method of the third example is different from that of the first example in that sidewall protective layers 112 are formed as shown in FIGS. 10A and 10B and that the sacrificial material layer 105′ is removed by etching using the variable resistance elements 110 and the sidewall protective layers 112 as the mask as shown in FIG. 10C.

FIG. 10A shows the step of forming a sidewall protective material layer 112′. The steps prior to this step are the same as the steps shown in FIGS. 4A to 4D, and the descriptions thereof are omitted hereinafter.

FIG. 10C shows the step of etching the sacrificial material layer 105′ using the variable resistance elements 110 and the sidewall protective layers 112 as the mask. The steps (shown in FIGS. 10D to 10F) posterior to this step are the same as those shown in FIGS. 4F to 4H, and the descriptions thereof are omitted hereinafter.

In the method of the third example, variable resistance elements 110 are formed as in the first example in accordance with the steps shown in FIGS. 4A to 4D.

Subsequently, as shown FIG. 10A, a sidewall protective material layer 112′ (thickness: 70 nm) is deposited on the sacrificial material layer 105′ and the variable resistance elements 110 by plasma CVD. The sidewall protective material layer 112′ is made of silicon nitride.

In general, a silicon nitride film showing good step coverage for convex portions is formed by low-pressure CVD. In the low-pressure CVD, since the reaction molecules have a long mean free path length, a thin film having good step coverage can be deposited. However, the low-pressure CVD is performed at a high temperature, i.e., in a deposition chamber at a temperature of 650° C. to 800° C. and is therefore difficult to be employed for film formation after formation of wiring.

In the third example, accordingly, the sidewall protective material layer 112′ is preferably formed by depositing silicon nitride through plasma CVD, which allows film formation at a temperature (250° C. to 400° C.) lower than that in the low-pressure CVD.

The variable resistance element 110 has a trapezoidal cross-section having a sidewall taper angle of less than 90°. Accordingly, even in plasma CVD, which is inferior to low-pressure CVD in the step coverage, the sidewall protective material layer 112′ made of silicon nitride can be formed so as to coat the sidewall of the variable resistance element 110 in a conformal manner. Herein, the term “conformal manner” refers to adaptability to the shape. The term “coating in a conformal manner” means that a sidewall protective material layer 112′ having an approximately uniform thickness is formed on the upper surface and the side surface of a variable resistance element 110 (or a layered product composed of a variable resistance element 110 and a hard mask 111 on the variable resistance element 110) without any gap and seamlessly. Alternatively, the sidewall protective material layer 112′ of silicon nitride may be formed by sputtering, for example, by reactive sputtering of silicon nitride using polycrystalline silicon as a target in a gas mixture of argon and nitrogen.

As shown in FIG. 10B, the sidewall protective material layer 112′ (on the second electrodes 109 and on the sacrificial material layer 105′) is removed by etchback except for the part on the sidewalls of the variable resistance elements 110 to form sidewall protective layers 112.

In etchback of the sidewall protective material layer 112′ of silicon nitride by reactive ion etching (RIE), in general, the etching rate in the ion incident direction (vertical direction) is higher than that in the direction (horizontal direction) other than the ion incident direction. Consequently, the sidewall protective layer 112 can be remained only on the sidewalls of the variable resistance elements 110.

As shown in FIG. 10C, the sacrificial material layer 105′ is dry-etched until the first insulating layer 101 is exposed using the second electrodes 109 of the variable resistance elements 110 or the hard masks 111 on the second electrodes 109 and the sidewall protective layer 112 as the mask.

In the third example, the sidewall of the variable resistance element is covered with the sidewall protective layer. As a result, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

The third example can also be modified as in the first to third embodiments and their modification examples.

### Fourth Embodiment

The nonvolatile storage device of a fourth embodiment is different from that of the third embodiment in that a diffusion-preventing layer is disposed on the first conductive layer.

The method for manufacturing a nonvolatile storage device of the fourth embodiment is different from that of the third embodiment in that a diffusion-preventing layer covering at least an upper surface of the first conductive layer is further formed before the forming of the sacrificial layer and that the contact plug passes through the sacrificial layer and the diffusion-preventing layer to be the contact plug connected to the first conductive layer.

The nonvolatile storage device of the fourth embodiment is different from that of the third embodiment in that a diffusion-preventing layer is further disposed so as to cover at least an upper surface of the first conductive layer and that the contact plug passes through the diffusion-preventing layer to be the contact plug in contact with the first conductive layer.

In such a configuration, for example, the first conductive layer is prevented from being exposed to the etching gas during the etching for forming the variable resistance element 10. As a result, diffusion and damage of the conductive layer in the post process can be prevented. Consequently, electrical defects are reduced; a reduction in yield can be prevented; and the reliability is improved.

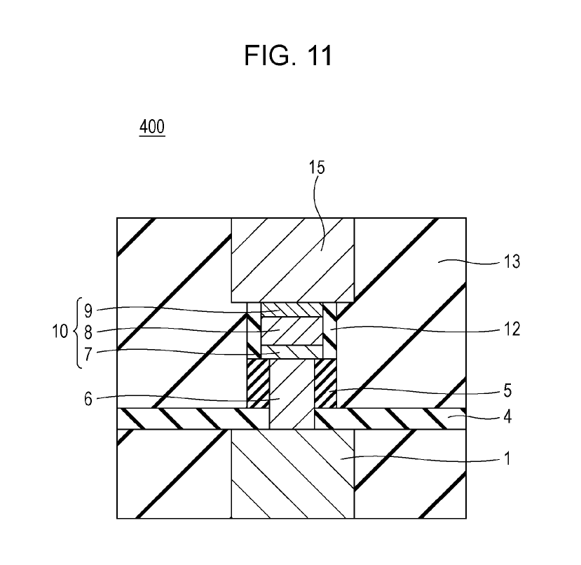

FIG. 11 is a cross-sectional view schematically illustrating an example of the configuration of a nonvolatile storage device according to the fourth embodiment. The nonvolatile storage device 400 of the fourth embodiment will be described with reference to FIG. 11.

The nonvolatile storage device 400 shown in FIG. 11 includes a diffusion-preventing layer 4.

The diffusion-preventing layer 4 covers the first conductive layer 1. The diffusion-preventing layer 4 is made of, for example, silicon nitride or another nitride (e.g., SiCN) and preferably has a thickness of 30 to 200 nm.

The contact 6 passes through the diffusion-preventing layer 4 and is in physical contact with the first conductive layer 1. In the example shown in FIG. 11, the contact 6 passes through the sacrificial layer 5 and the diffusion-preventing layer 4 and is in physical contact with the first conductive layer 1.

The nonvolatile storage device 400 has the same configuration as that of the nonvolatile storage device 300 of the third embodiment except for the points described above. The components common to FIGS. 8 and 11 are, therefore, given the same reference numerals and names, and detailed descriptions thereof will be omitted.

The fourth embodiment can also be modified as in the first to third embodiments and their modification examples.

### Fourth Example

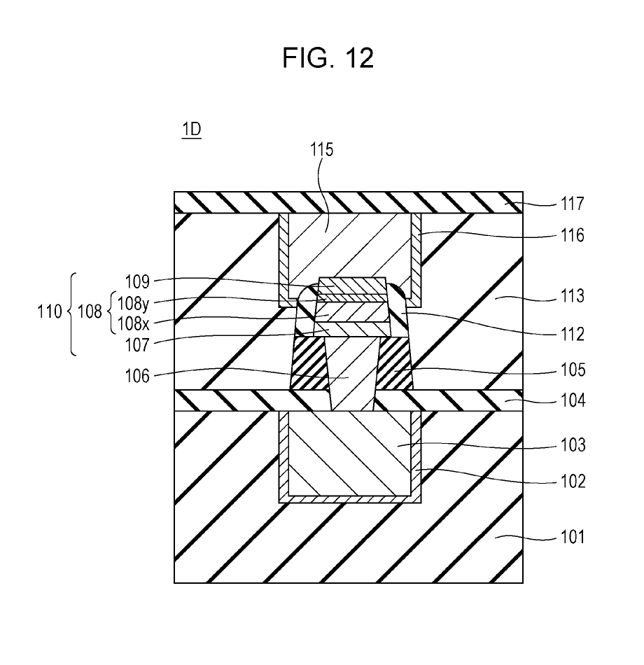

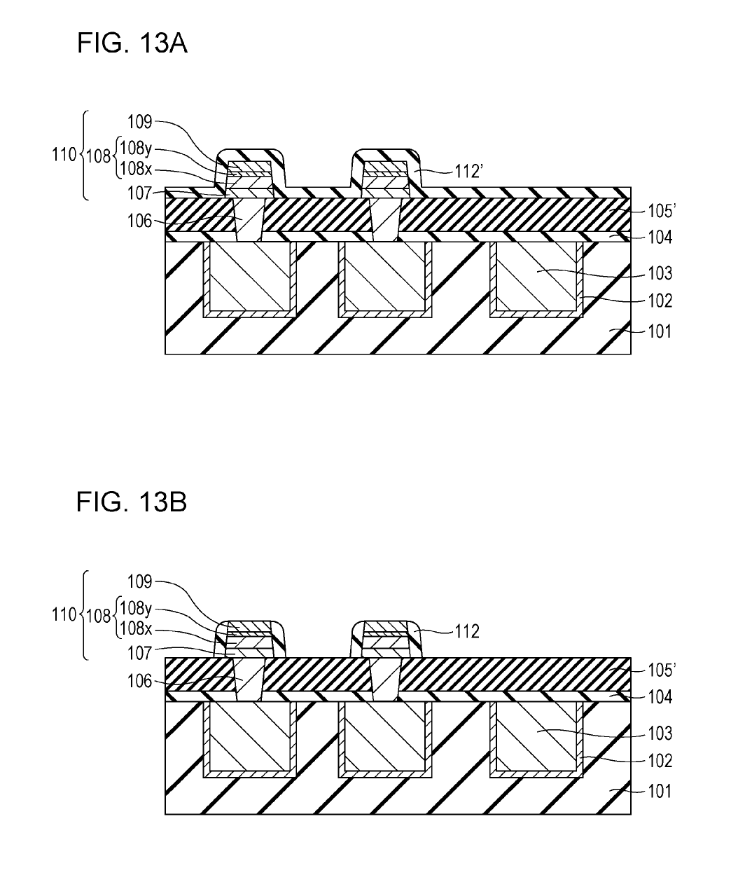

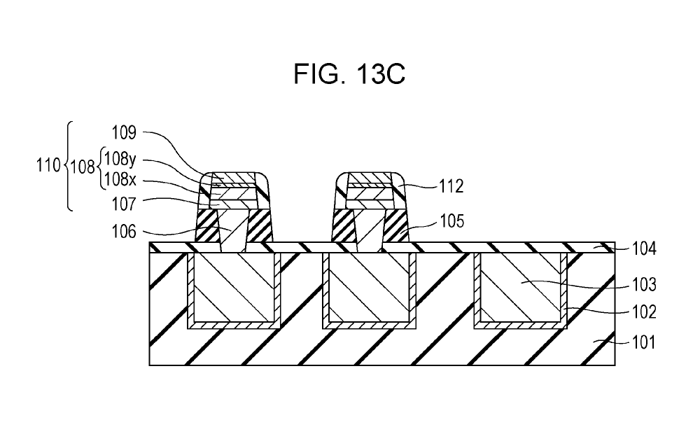

A fourth example will now be described with reference to FIGS. 12 and 13A to 13C as an example of the nonvolatile storage device and the method of producing a nonvolatile storage unit of the nonvolatile memory devices according to the fourth embodiment.

The nonvolatile storage device 1D of the fourth example is different from the nonvolatile storage device 1C of the third example in that a first diffusion-preventing layer 104 and a second diffusion-preventing layer 117 are disposed above the first conductive layer 1.

### Device Configuration

The configuration of the nonvolatile storage device 1D will be described with reference to FIG. 12. FIG. 12 is a cross-sectional view schematically illustrating the configuration of the nonvolatile storage device 1D according to the fourth example. The nonvolatile storage device 1D shown in FIG. 12 is one memory cell of a memory cell array or memory body of a general semiconductor storage apparatus.

That is, the nonvolatile storage unit includes a plurality of the nonvolatile storage devices 1D shown in FIG. 12. Specifically, the nonvolatile storage unit includes a memory cell array composed of a plurality of the nonvolatile storage devices 1D, and may further include a driving circuit for driving the memory cell array.

As shown in FIG. 12, the nonvolatile storage device 1D includes a first diffusion-preventing layer 104 and a second diffusion-preventing layer 117.

The first diffusion-preventing layer 104 and the second diffusion-preventing layer 117 can have the same configurations as those in the second example, and the detailed descriptions thereof are omitted.

The contact 106 passes through the first diffusion-preventing layer 104 and the sacrificial layer 105 and is in contact with the first conductive layer 103. The second insulating layer 113 is disposed on the first diffusion-preventing layer 104.

The nonvolatile storage device 1D of the fourth example has the same configuration as that of the nonvolatile storage device 1C of the third example except for the points described above. The components common to FIGS. 9 and 12 are, therefore, given the same reference numerals and names, and detailed descriptions thereof will be omitted.

### Method of Production

An example of the method of producing a nonvolatile storage unit of the nonvolatile storage devices 1D in the fourth example will be described with reference to FIGS. 13A to 13C.

The method of the fourth example is different from that of the third example in that a first diffusion-preventing layer 104 and a second diffusion-preventing layer 117 are formed and that the sacrificial material layer 105′ is etched until the first diffusion-preventing layer 104 is exposed using the variable resistance elements 110 and the sidewall protective layers 112 as the mask.

FIG. 13A shows the step of forming a sidewall protective material layer 112′. The steps prior to this step are the same as the steps shown in FIGS. 4A to 4D, and the descriptions thereof are omitted hereinafter.

FIG. 13C shows the step of etching the sacrificial material layer 105′ using the variable resistance elements 110 and the sidewall protective layers 112 as the mask. The steps posterior to this step are the same as those shown in FIGS. 4F to 4H, and the descriptions thereof are omitted hereinafter.

In the method of the fourth example, the variable resistance elements 110 are formed through the steps shown in FIGS. 4A to 4D as in the second example.

Subsequently, as shown in FIG. 13A, a sidewall protective material layer 112′ (thickness: 70 nm) is deposited on the sacrificial material layer 105′ and the variable resistance elements 110 by plasma CVD. The sidewall protective material layer 112′ is made of silicon nitride.

The sidewall protective material layer 112′ of silicon nitride may be formed as in the third example. As described in the third example, the sidewall protective material layer 112′ of silicon nitride may be formed by sputtering.

As shown FIG. 13B, the sidewall protective material layer 112′ (on the second electrodes 109 and on the sacrificial material layer 105′) is removed by etchback except for the part on the sidewalls of the variable resistance elements 110 to form sidewall protective layers 112. The process of forming the sidewall protective layer 112 by etchback of the sidewall protective material layer 112′ is the same as that described in the third example with reference to FIG. 10B, and the description thereof is omitted.

The upper surface of the second electrode 109 may have a rounded square shape.

As shown in FIG. 13C, the sacrificial material layer 105′ is dry-etched until the first diffusion-preventing layer 104 is exposed using the second electrodes 109 of the variable resistance elements 110 or the hard masks 111 on the second electrodes 109 and the sidewall protective layer 112 as the mask.

In the step of dry etching of the sacrificial material layer 105′ of silicon oxide in the fourth example, the chamber pressure and the etching gas can be, for example, those in the second example, and the description thereof is omitted.

In the fourth example, the sidewall of the variable resistance element is covered with the sidewall protective layer. As a result, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

In addition, the first conductive layer can be prevented from being exposed during the etching of the sacrificial material layer. As a result, diffusion and damage of the conductive layer in the post process can be prevented. Consequently, electrical defects are reduced; a reduction in yield can be prevented; and the reliability is improved.

The fourth example can also be modified as in the first to fourth embodiments and their modification examples.

### Fifth Embodiment

The nonvolatile storage device of a fifth embodiment is different from that of a modification example of the first embodiment in that sidewall protective layers are disposed on the sidewalls of the variable resistance element and the sacrificial layer.

The method for manufacturing a nonvolatile storage device in the fifth embodiment is different from that of the first embodiment in that the sacrificial layer is removed such that an outer edge of the variable resistance element is coincided with an outer edge of the sacrificial layer in a plan view and that a sidewall protective layer of an insulating material is formed so as to cover the sidewalls of the variable resistance element and the sacrificial layer after the removing of the sacrificial layer and before the forming of the second conductive layer.

The nonvolatile storage device of the fifth embodiment is different from that of the first embodiment in that a sacrificial layer covering the sidewall of the contact plug is further disposed between the variable resistance element and the first conductive layer, and a sidewall protective layer including an insulating material covers both sidewalls of the variable resistance element and the sacrificial layer and that an outer edge of the variable resistance element is coincided with an outer edge of the sacrificial layer in a plan view, and the one single insulating layer is in contact with the sidewall protective layer.

In this configuration, the sidewall of the variable resistance element is covered with the sidewall protective layer. As a result, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

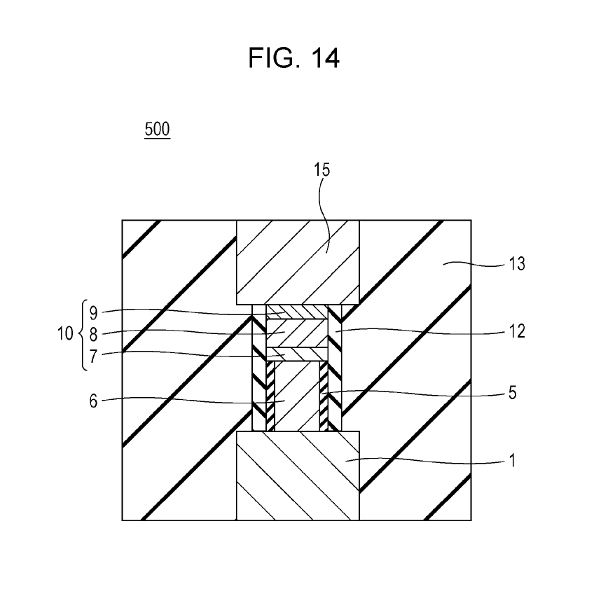

FIG. 14 is a cross-sectional view schematically illustrating an example of the configuration of a nonvolatile storage device according to the fifth embodiment. The nonvolatile storage device 500 of the fifth embodiment will now be described with reference to FIG. 14.

The nonvolatile storage device 500 shown in FIG. 14 includes a sacrificial layer 5 and a sidewall protective layer 12. The sacrificial layer 5 is disposed on the first conductive layer 1 and between the variable resistance element 10 and the first conductive layer 1. The sidewall protective layer 12 is made of an insulating material and covers the sidewalls of the variable resistance element 10 and the sacrificial layer 5. The sidewall protective layer 12 may cover at least a part of the sidewall of the variable resistance element 10 and at least a part of the sidewall of the sacrificial layer 5. The contact 6 passes through the sacrificial layer 5 and is in contact with the first conductive layer 1.

The outer edge of the variable resistance element 10 and the outer edge of the sacrificial layer 5 coincide with each other in a plan view. The insulating layer 13 is in physical contact with the sidewall protective layer 12.

The nonvolatile storage device 500 has the same configuration as that of the nonvolatile storage device 100A according to a modification example of the first embodiment except for the points described above. The components common to FIGS. 2 and 14 are, therefore, given the same reference numerals and names, and detailed descriptions thereof will be omitted.

The fifth embodiment can also be modified as in the first to fourth embodiments and their modification examples.

### Fifth Example

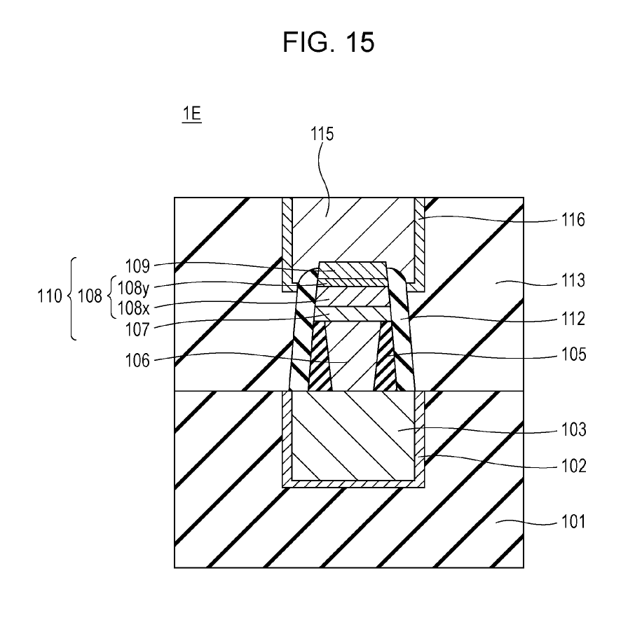

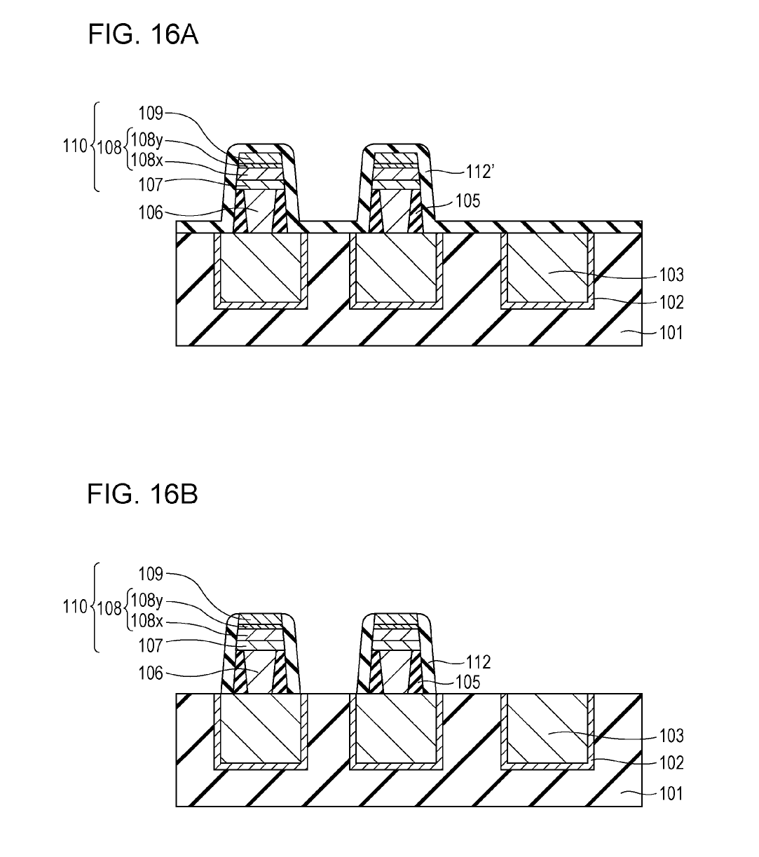

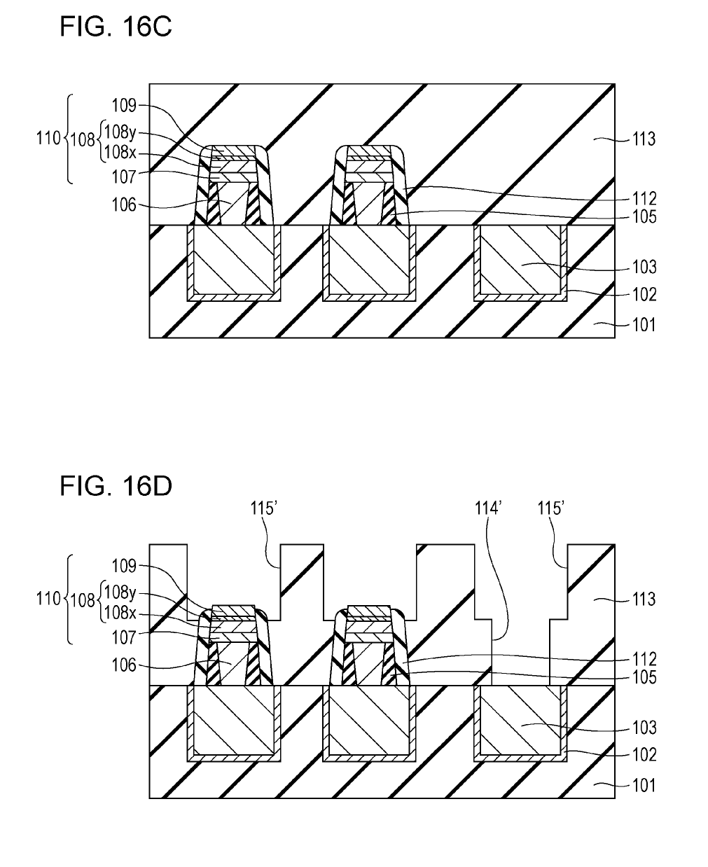

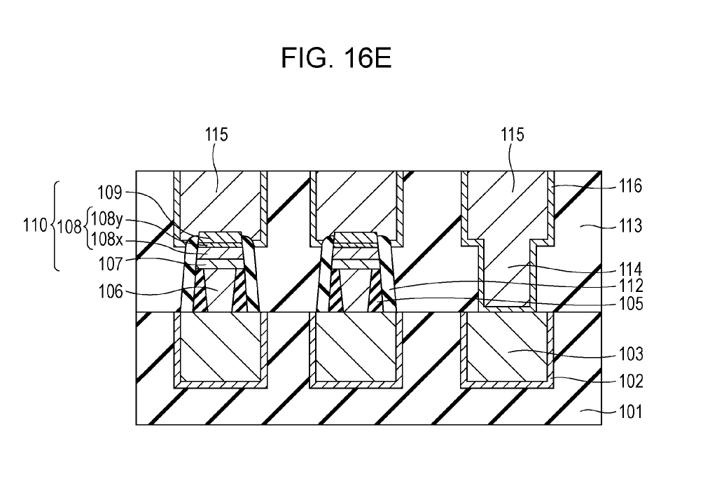

A fifth example will now be described with reference to FIGS. 15 and 16A to 16E as an example of the nonvolatile storage device 1E and the method of producing a nonvolatile storage unit of the nonvolatile memory devices 1E according to the fifth embodiment.

The nonvolatile storage device 1E of the fifth example is different from the nonvolatile storage device 1A of the first example in that a sidewall protective layer 112 is disposed on the sidewalls of the variable resistance element 110 and the sacrificial layer 105.

### Device Configuration

The configuration of the nonvolatile storage device 1E including the variable resistance element 110 and the sidewall protective layer 112 of the fifth example will be described with reference to FIG. 15. FIG. 15 is a cross-sectional view schematically illustrating the configuration of the nonvolatile storage device 1E according to the fifth example. The nonvolatile storage device 1E shown in FIG. 15 is one memory cell of a memory cell array or memory body of a general semiconductor storage apparatus.

That is, the nonvolatile storage unit includes a plurality of the nonvolatile storage devices 1E shown in FIG. 15. Specifically, the nonvolatile storage unit includes a memory cell array composed of a plurality of the nonvolatile storage devices 1E, and may further include a driving circuit for driving the memory cell array.

As shown in FIG. 15, the nonvolatile storage device 1E includes a sidewall protective layer 112. The sidewall protective layer 112 covers the sidewalls of the variable resistance element 110 and the sacrificial layer 105. The sidewall protective layer 112 is made of an insulating material.

The sidewall protective layer 112 in the fifth example may be made of the same material as that of the sidewall protective layer in the third example.

The nonvolatile storage device 1E of the fifth example has the same configuration as that of the nonvolatile storage device 1A of the first example except for the points described above. The components common to FIGS. 3A and 15 are, therefore, given the same reference numerals and names, and detailed descriptions thereof will be omitted.

### Method of Production

An example of the method of producing a nonvolatile storage unit of the nonvolatile storage devices 1E in the fifth example will be described with reference to FIGS. 16A to 16E.

The method of the fifth example is different from that of the first example in that a sidewall protective layer 112 is formed as shown in FIGS. 16A and 16B.

FIG. 16A shows a step of forming a sidewall protective material layer 112′ made of silicon nitride. The steps prior to this step are the same as the steps shown in FIGS. 4A to 4E, and the descriptions thereof are omitted hereinafter.

FIG. 16A shows a step of forming a sidewall protective material layer 112′ of silicon nitride, and FIG. 16B shows a step of forming sidewall protective layers 112 of silicon nitride. These steps are the same as those shown in FIGS. 10A and 10B except that the sacrificial material layer 105′ is etched until the upper surface of the first insulating layer 101 is exposed, and the descriptions thereof are omitted hereinafter.

FIG. 16C shows a step of depositing a second insulating layer 113. The steps posterior to this step are the same as those shown in FIGS. 4F to 4H, and the descriptions thereof are omitted hereinafter.

In the fifth example, the sidewall protective layer 112 covers both the variable resistance element 110 and the sacrificial layer 105. Consequently, the amount of the sacrificial layer 105 can be relatively reduced compared to those of the devices having the configurations shown in FIGS. 9 and 12.

In addition, since the sidewall protective layer covers the sidewall of the variable resistance element, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

### Sixth Embodiment

The nonvolatile storage device of a sixth embodiment is different from that of the fifth embodiment in that a diffusion-preventing layer is disposed on the first conductive layer.

The method for manufacturing the nonvolatile storage device of the sixth embodiment is different from that of the fifth embodiment in that a diffusion-preventing layer covering at least an upper surface of the first conductive layer is further formed before the forming of the sacrificial layer and that the contact plug passes through the sacrificial layer and the diffusion-preventing layer to be the contact plug in contact with the first conductive layer.

The nonvolatile storage device of the sixth embodiment is different from that of the fifth embodiment in that a diffusion-preventing layer covers at least an upper surface of the first conductive layer and that the contact plug passes through the diffusion-preventing layer to be the contact plug in contact with the first conductive layer.

In such a configuration, for example, the first conductive layer is prevented from being exposed to the etching gas during the etching for forming the variable resistance element 10. As a result, diffusion and damage of the conductive layer in the post process can be prevented. Consequently, electrical defects are reduced; a reduction in yield can be prevented; and the reliability is improved.

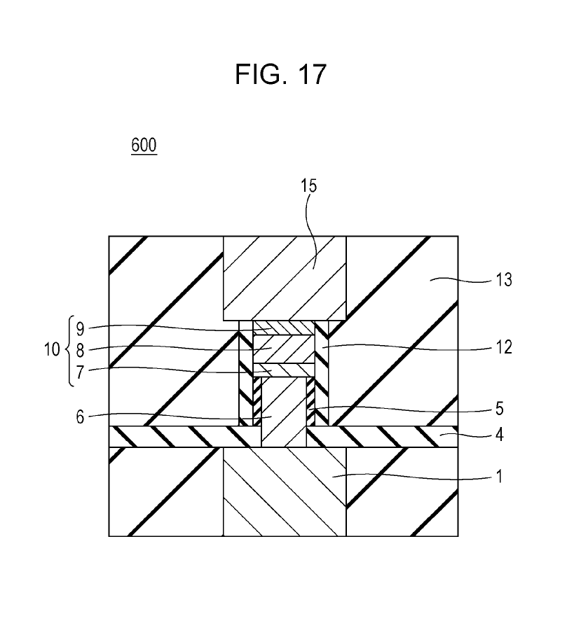

FIG. 17 is a cross-sectional view schematically illustrating an example of the configuration of a nonvolatile storage device according to the sixth embodiment. The nonvolatile storage device 600 of the sixth embodiment will now be described with reference to FIG. 17.

The nonvolatile storage device 600 shown in FIG. 17 includes a diffusion-preventing layer 4. The diffusion-preventing layer 4 has the same configuration as that in the second embodiment, and the detailed description thereof is omitted.

The contact 6 passes through the diffusion-preventing layer 4 and is in physical contact with the first conductive layer 1. In the example shown in FIG. 17, the contact 6 passes through the sacrificial layer 5 and the diffusion-preventing layer 4 and is in physical contact with the first conductive layer 1.

The nonvolatile storage device 600 has the same configuration as that of the nonvolatile storage device 500 of the fifth embodiment except for the points described above. The components common to FIGS. 14 and 17 are, therefore, given the same reference numerals and names, and detailed descriptions thereof will be omitted.

The sixth embodiment can also be modified as in the first to fifth embodiments and their modification examples.

### Sixth Example

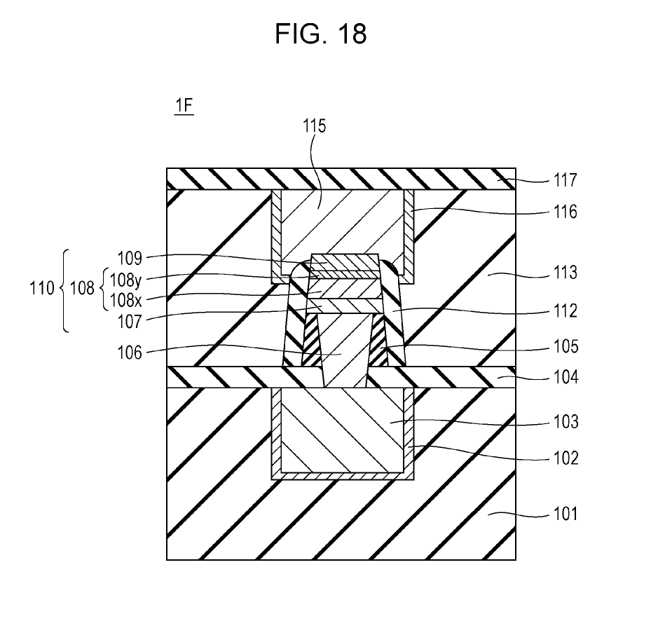

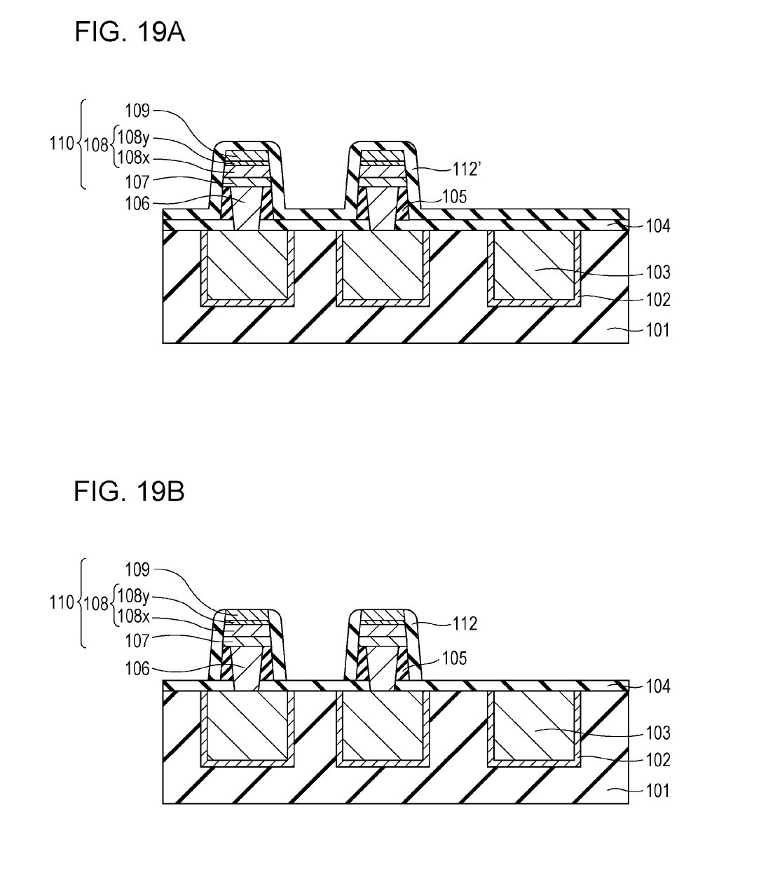

A sixth example will now be described with reference to FIGS. 18, 19A, and 19B as an example of the nonvolatile storage device and the method of producing a nonvolatile storage unit of the nonvolatile memory devices according to the sixth embodiment.

The nonvolatile storage device 1F of the sixth example is different from the nonvolatile storage device 1E of the fifth example in that a first diffusion-preventing layer 104 and a second diffusion-preventing layer 117 are disposed above the first conductive layer.

### Structure of Element

The configuration of the nonvolatile storage device 1F including the variable resistance element 110 and the sidewall protective layer 112 according to the sixth example will be described with reference to FIG. 18. FIG. 18 is a cross-sectional view illustrating the nonvolatile storage device 1F according to the sixth example. The nonvolatile storage device 1F shown in FIG. 18 is one memory cell of a memory cell array or memory body of a general semiconductor storage apparatus.

That is, the nonvolatile storage unit includes a plurality of the nonvolatile storage devices 1F shown in FIG. 18. Specifically, the nonvolatile storage unit includes a memory cell array composed of a plurality of the nonvolatile storage devices 1F, and may further include a driving circuit for driving the memory cell array.

As shown in FIG. 18, the nonvolatile storage device 1F includes a first diffusion-preventing layer 104 and a second diffusion-preventing layer 117.

The first diffusion-preventing layer 104 and the second diffusion-preventing layer 117 have the same configurations as those described in the second example, and the detailed descriptions thereof are omitted.

The contact 106 passes through the first diffusion-preventing layer 104 and the sacrificial layer 105 and is in contact with the first conductive layer 103. The second insulating layer 113 is disposed on the first diffusion-preventing layer 104.

The nonvolatile storage device 1F of the sixth example has the same configuration as that of the nonvolatile storage device 1E of the fifth example except for the points described above. The components common to FIGS. 15 and 18 are, therefore, given the same reference numerals and names, and detailed descriptions thereof will be omitted.

### Method of Production

An example of the method of producing a nonvolatile storage unit of the nonvolatile storage devices 1F in the sixth example will be described with reference to FIGS. 19A and 19B.

The method of the sixth example is different from that of the second example in that the sidewall protective material layer 112′ is formed as shown in FIG. 19A and the sidewall protective layers 112 are formed as shown in FIG. 19B.

FIG. 19A shows the step of forming the sidewall protective material layer 112′ of silicon nitride. The steps before this step are the same as those shown in FIGS. 7A to 7E, and the descriptions thereof are omitted hereinafter.

FIG. 19A shows the step of forming the sidewall protective material layer 112′ of silicon nitride, and FIG. 19B shows the step of forming the sidewall protective layers 112 of silicon nitride. These steps are the same as those shown in FIGS. 16A and 16B, and the descriptions thereof are omitted hereinafter.

The steps after the step of forming the sidewall protective layer 112 of silicon nitride shown in FIG. 19B are the same as those shown in FIGS. 16C to 16E, and the descriptions thereof are omitted hereinafter.

As in the step shown in FIG. 16E, a second conductive layer 115, a second insulating layer 113, and a drawn contact 114 are formed, and a second diffusion-preventing layer 117 is then formed. On this occasion, the second insulating layer 113 and the second conductive layer 115 are formed, and a silicon nitride layer having a thickness of 30 to 200 nm, for example, 50 nm, is then deposited by plasma CVD or another method to form the second diffusion-preventing layer 117 covering the second conductive layer 115 and the second insulating layer 113.

In the sixth example, the sidewall protective layer 112 covers both the variable resistance element 110 and the sacrificial layer 105. Consequently, the amount of the sacrificial layer 105 can be relatively reduced compared to those of the devices having the configurations shown in FIGS. 9 and 12.

The sidewall of the variable resistance element is covered with the sidewall protective layer. As a result, oxidation can be prevented from progressing from the side of the variable resistance layer, during the formation and heat treatment of the insulating layer after the formation of the variable resistance element. Consequently, the variation in effective cross-sectional area of the variable resistance layer can be prevented.

In addition, since the sidewall of the variable resistance element is covered with the sidewall protective layer, a leakage path can be prevented from being formed between the second conductive layer and the variable resistance layer in the step of forming the second conductive layer. The existence of the sidewall protective layer allows the second conductive layer to be formed so as to spread also under the plane defined by the upper surface of the second electrode and allows the second electrode and the second conductive layer to be in secure contact with each other. As a result, the variation in the density of current flowing in the variable resistance layer can be prevented; electrical defects are reduced; a reduction in yield can be prevented; and the reliability is improved.

### Modification Examples of the First to Sixth Examples

In the first to sixth examples, configurations each including a first electrode 107, a first variable resistance layer 108x, a second variable resistance layer 108y, and a second electrode 109 laminated on a substrate in this order have been described. The order of lamination may be reversed. That is, a second electrode 109, a second variable resistance layer 108y, a first variable resistance layer 108x, and a first electrode 107 may be laminated on a substrate in this order.

The sidewall protective layer 112 may be made of an oxide, nitride, or oxynitride, such as aluminum oxide or titanium oxide, having an insulating property and an oxygen barrier property, instead of silicon nitride.

The nonvolatile storage device and the method of producing the nonvolatile storage device have been described based on embodiments, but the present disclosure is not limited to these embodiments, and various modifications made by those skilled in the arts within the gist of the present disclosure are included in the scope of the present disclosure. In addition, the components of different embodiments may be appropriately combined within the gist of the present disclosure.

The present disclosure provides a resistive random access nonvolatile storage device and a method of producing the nonvolatile storage device. The present disclosure can achieve a nonvolatile memory that stably behaves and has high reliability and is therefore useful in various fields of electronics using nonvolatile memories including resistive random access nonvolatile storage devices.

What is claimed is:

1. A method for manufacturing a nonvolatile storage device, the method comprising:
forming a first conductive layer on a substrate;
forming a sacrificial layer covering the first conductive layer;
forming a contact plug passing through the sacrificial layer to be the contact plug in contact with the first conductive layer, the contact plug including a conductive material;
forming a variable resistance element covering the upper surface of the contact plug;
removing the sacrificial layer other than a part of the sacrtificial layer that covers a sidewall of the contact plug;
forming one single insulating layer that is directly or indirectly in contact with the sidewall of the contact plug and that is directly or indirectly in contact with the variable resistance element; and
forming a second conductive layer on the variable resistance element.

2. The method according to claim 1,
wherein at the removing of the sacrificial layer, an outer edge of the variable resistance element is coincided with an outer edge of the sacrificial layer in a plan view.

3. The method according to claim 1, further comprising:
forming a sidewall protective layer covering the sidewall of the variable resistance element, the sidewall protective layer including an insulating material, after the forming of the variable resistance element and before the removing of the sacrificial layer,
wherein at the removing of the sacrificial layer, an outer edge of the sidewall protective layer is coincided with an outer edge of the sacrificial layer in a plan view.

4. The method according to claim 1, further comprising:
forming a sidewall protective layer covering the sidewall of the variable resistance element and the sidewall of the sacrificial layer, the sidewall protective layer including an insulating material, after the removing of the sacrificial layer and before the forming of the second conductive layer,
wherein at the removing of the sacrificial layer, an outer edge of the variable resistance element is coincided with an outer edge of the sacrificial layer in a plan view.

5. The method according to claim 1, further comprising:
forming a diffusion-preventing layer covering at least an upper surface of the first conductive layer, before the forming of the sacrificial layer,
wherein the contact plug passes through the sacrificial layer and the diffusion-preventing layer to be the contact plug in contact with the first conductive layer.

6. The method according to claim 1, wherein the one single insulating layer has a relative dielectric constant of 2.2 or more and 3.0 or less.

7. The method according to claim 1, wherein the one single insulating layer has pores having an average pore size of 2 nm or more and 6 nm or less.

8. The method according to claim 1, wherein the one single insulating layer has a carbon concentration of 10% or more and 30% or less as the atomic composition percentage.

9. The method according to claim 1, wherein the one single insulating layer has a mechanical strength lower than a mechanical strength of the sacrificial layer.

10. The method of producing a nonvolatile storage device according to claim 1, wherein the variable resistance element has a first electrode, a variable resistance layer, and a second electrode laminated in this order.

11. A nonvolatile storage device comprising:
a first conductive layer disposed on a substrate;
a contact plug including a conductive material and disposed on the first conductive layer;
a variable resistance element that covers the upper surface of the contact plug, resistance of the variable resistance element changing in accordance with an voltage applied to the variable resistance element;
one single insulating layer that is directly or indirectly in contact with a sidewall of the contact plug and that is directly or indirectly in contact with the variable resistance element; and
a second conductive layer disposed on the variable resistance element.

12. The nonvolatile storage device according to claim 11, further comprising:
a sacrificial layer that covers the sidewall of the contact plug between the variable resistance element and the first conductive layer,
wherein
an outer edge of the variable resistance element is coincided with an outer edge of the sacrificial layer in a plan view; and
the one single insulating layer is in contact with a sidewall of the variable resistance element and the sidewall of the sacrificial layer.

13. The nonvolatile storage device according to claim 11, further comprising:
a sidewall protective layer including an insulating material and covering a sidewall of the variable resistance element;
a sacrificial layer that covers the sidewall of the contact plug between the variable resistance element and the first conductive layer and between the sidewall protective layer and the first conductive layer,
wherein
an outer edge of the sidewall protective layer is coincided with an outer edge of the sacrificial layer in a plan view; and
the one single insulating layer is in contact with the sidewall protective layer and the sacrificial layer.

14. The nonvolatile storage device according to claim 11, further comprising:
a sacrificial layer that covers the sidewall of the contact plug between the variable resistance element and the first conductive layer; and
a sidewall protective layer including an insulating material and covering both sidewalls of the variable resistance element and the sacrificial layer,
wherein
an outer edge of the variable resistance element is coincided with an outer edge of the sacrificial layer in a plan view; and
the one single insulating layer is in contact with the sidewall protective layer.

15. The nonvolatile storage device according to claim 11, further comprising:
a diffusion-preventing layer covering at least an upper surface of the first conductive layer,
wherein the contact plug passes through the diffusion-preventing layer to be the contact plug in contact with the first conductive layer.

16. The nonvolatile storage device according to claim 11, wherein the one single insulating layer has a relative dielectric constant of 2.2 or more and 3.0 or less.

17. The nonvolatile storage device according to claim 11, wherein the one single insulating layer has pores having an average pore size of 2 nm or more and 6 nm or less.

18. The nonvolatile storage device according to claim 11, wherein the one single insulating layer has a carbon concentration of 10% or more and 30% or less as the atomic composition percentage.

19. The nonvolatile storage device according to claim 11, further comprising:
a sacrificial layer that covers the sidewall of the contact plug between the first conductive layer and the variable resistance element,
wherein the one single insulating layer has a mechanical strength lower than a mechanical strength of the sacrificial layer.

20. The nonvolatile storage device according to claim 11, wherein the variable resistance element has a first electrode, a variable resistance layer, and a second electrode laminated in this order.
